(19) United States
(12) Patent Application Publication
(10) Pub. No.: US 2019/0189682 A1
(43) Pub. Date: Jun. 20, 2019

(54) MONOLITHIC SEGMENTED LED ARRAY ARCHITECTURE WITH TRANSPARENT COMMON N-CONTACT

(71) Applicant: Lumileds LLC, San Jose, CA (US)

(72) Inventors: Erik YOUNG, San Jose, CA (US); Joseph Robert FLEMISH, Palo Alto, CA (US); Ashish TANDON, Sunnyvale, CA (US); Rajat SHARMA, San Jose, CA (US); Andrei PAPOU, San Jose, CA (US); Wen YU, Pleasanton, CA (US); Yu-Chen SHEN, Sunnyvale, CA (US); Luke GORDON, Santa Barbara, CA (US)

(73) Assignee: Lumileds LLC, San Jose, CA (US)

(21) Appl. No.: 16/226,239

(22) Filed: Dec. 19, 2018

Related U.S. Application Data
(60) Provisional application No. 62/608,307, filed on Dec. 20, 2017.

(30) Foreign Application Priority Data
Feb. 28, 2018 (EP) 18159072.0

(51) Int. Cl. H01L 27/15; H01L 33/32; H01L 33/50; H01L 33/60; H01L 33/62; H01L 33/00; F21S 41/153

(52) U.S. Cl. CPC H01L 27/156; H01L 33/32; H01L 33/501; H01L 33/60; H01L 33/62; F21Y 2115/10; F21S 41/153; H01L 2933/0041; H01L 2933/0066; H01L 2933/0058; H01L 33/007

(57) ABSTRACT

A light emitting diode (LED) array may include an epitaxial layer comprising a first pixel and a second pixel separated by an isolation region. A reflective layer may be formed on the epitaxial layer. A p-type contact layer may be formed on the reflective layer. The isolation region may have a width that is at least a width of a trench formed in a p-type contact layer.

### CROSS REFERENCE TO RELATED APPLICATIONS

This application claims the benefit of U.S. Provisional Application No. 62/608,307 filed on Dec. 20, 2017 and EP Patent Application No. 18159072.0 filed on Feb. 28, 2018, the contents of which are hereby incorporated by reference herein.

### BACKGROUND

Semiconductor light-emitting devices including light emitting diodes (LEDs), resonant cavity light emitting diodes (RCLEDs), vertical cavity laser diodes (VCSELs), and edge emitting lasers are among the most efficient light sources currently available. Materials systems currently of interest in the manufacture of high-brightness light emitting devices capable of operation across the visible spectrum include Group III-V semiconductors, particularly binary, ternary, and quaternary alloys of gallium, aluminum, indium, and nitrogen, also referred to as III-nitride materials.

Typically, III-nitride light emitting devices are fabricated by epitaxially growing a stack of semiconductor layers of different compositions and dopant concentrations on a sapphire, silicon carbide, III-nitride, or other suitable substrate by metal-organic chemical vapor deposition (MOCVD), molecular beam epitaxy (MBE), or other epitaxial techniques. The stack often includes one or more n-type layers doped with, for example, silicon, formed over the substrate, one or more light emitting layers in an active region formed over the n-type layer or layers, and one or more p-type layers doped with, for example, magnesium, formed over the active region. Electrical contacts are formed on the n- and p-type regions.

### SUMMARY

A device may include an isolation region in an epitaxial layer. The isolation region may have a width that is at least a width of a trench formed in a p-type contact layer and a reflective layer on the epitaxial layer.

A light emitting diode (LED) array may include an epitaxial layer having a first pixel and a second pixel separated by an isolation region. A reflective layer may be formed on the epitaxial layer. A p-type contact layer may be formed on the reflective layer. The isolation region may have a width that is at least a width of a trench formed in a p-type contact layer.

A method of forming a device may include forming a trench in a p-type contact layer and a reflective layer to expose an epitaxial layer. An isolation region may be formed in the epitaxial layer exposed by the trench using ion implantation. The isolation region may separate a first pixel and a second pixel and having a width that is at least a width of the trench.

### BRIEF DESCRIPTION OF THE DRAWINGS

A more detailed understanding can be had from the following description, given by way of example in conjunction with the accompanying drawings wherein:

FIG. 1A is a top view illustration of an LED array with an exploded portion;

FIG. 1B is a cross sectional illustration of an LED array with trenches;

FIG. 1C is a perspective illustration of another LED array with trenches;

FIG. 1D is a cross section view of an epitaxial layer formed on a sapphire substrate;

FIG. 1E is a cross section view illustrating forming a reflective layer on the epitaxial layer;

FIG. 1F is a cross section view illustrating forming a resist layer on the reflective layer;

FIG. 1G is a cross section view illustrating patterning the resist layer to form one or more trenches;

FIG. 1H is a cross section view illustrating removing portions of the reflective layer exposed by the one or more trenches;

FIG. 1I is a cross section view illustrating forming isolation regions within the epitaxial layer;

FIG. 1J is a cross section view illustrating another example of forming isolation regions within the epitaxial layer;

FIG. 1K is a cross section view illustrating another example of forming isolation regions within the epitaxial layer;

FIG. 1L is a cross section view illustrating removing the resist layer;

FIG. 1M is a cross section view illustrating forming a p-type contact layer on the reflective layer;

FIG. 1N is a cross section view illustrating removing the sapphire substrate;

FIG. 1O is a cross section view illustrating forming a common n-contact layer on a bottom surface of the epitaxial layer;

FIG. 1P is a cross section view of a reflective layer formed on an epitaxial layer;

FIG. 1Q is a cross section view illustrating removing portions of the reflective layer 1 and the epitaxial layer;

FIG. 1R is a cross section view of forming a dielectric layer 152 and an n-type contact;

FIG. 1S is a cross section view of a LED array formed on a sapphire substrate;

FIG. 1T illustrates removing the sapphire substrate from the epitaxial layer;

FIG. 1U illustrates forming walls on the lower surface of the epitaxial layer;

FIG. 1V illustrates forming a wavelength converting layer within wells formed by the walls;

FIG. 1W illustrates removing portions of the sapphire substrate from the epitaxial layer;

FIG. 1X illustrates forming a wavelength converting layer within the wells;

FIG. 1Y illustrates a cross section view of a LED array formed on a sapphire substrate;

FIG. 1Z illustrates removing the sapphire substrate;

FIG. 1AA illustrates forming a wavelength converting layer within the wells;

FIG. 1AB illustrates a cross section view of a LED array formed on a sapphire substrate;

FIG. 1AC illustrates removing the sapphire substrate;

FIG. 1AD illustrates forming a wavelength converting layer within the wells;

FIG. 1AE is a flowchart illustrating a method of forming a device;

FIG. 2A is a top view of the electronics board with LED array attached to the substrate at the LED device attach region in one embodiment;

FIG. 2B is a diagram of one embodiment of a two channel integrated LED lighting system with electronic components mounted on two surfaces of a circuit board;

FIG. 2C is an example vehicle headlamp system; and

FIG. 3 shows an example illumination system.

### DETAILED DESCRIPTION

Examples of different light illumination systems and/or light emitting diode (“LED”) implementations will be described more fully hereinafter with reference to the accompanying drawings. These examples are not mutually exclusive, and features found in one example may be combined with features found in one or more other examples to achieve additional implementations. Accordingly, it will be understood that the examples shown in the accompanying drawings are provided for illustrative purposes only and they are not intended to limit the disclosure in any way. Like numbers refer to like elements throughout.

It will be understood that, although the terms first, second, third, etc. may be used herein to describe various elements, these elements should not be limited by these terms. These terms may be used to distinguish one element from another. For example, a first element may be termed a second element and a second element may be termed a first element without departing from the scope of the present invention. As used herein, the term “and/or” may include any and all combinations of one or more of the associated listed items.

It will be understood that when an element such as a layer, region, or substrate is referred to as being “on” or extending “onto” another element, it may be directly on or extend directly onto the other element or intervening elements may also be present. In contrast, when an element is referred to as being “directly on” or extending “directly onto” another element, there may be no intervening elements present. It will also be understood that when an element is referred to as being “connected” or “coupled” to another element, it may be directly connected or coupled to the other element and/or connected or coupled to the other element via one or more intervening elements. In contrast, when an element is referred to as being “directly connected” or “directly coupled” to another element, there are no intervening elements present between the element and the other element. It will be understood that these terms are intended to encompass different orientations of the element in addition to any orientation depicted in the figures.

Relative terms such as “below,” “above,” “upper,”, “lower,” “horizontal” or “vertical” may be used herein to describe a relationship of one element, layer, or region to another element, layer, or region as illustrated in the figures. It will be understood that these terms are intended to encompass different orientations of the device in addition to the orientation depicted in the figures.

Semiconductor light emitting devices (LEDs) or optical power emitting devices, such as devices that emit ultraviolet (UV) or infrared (IR) optical power, are among the most efficient light sources currently available. These devices (hereinafter “LEDs”), may include light emitting diodes, resonant cavity light emitting diodes, vertical cavity laser diodes, edge emitting lasers, or the like. Due to their compact size and lower power requirements, for example, LEDs may be attractive candidates for many different applications. For example, they may be used as light sources (e.g., flash lights and camera flashes) for hand-held battery-powered devices, such as cameras and cell phones. They may also be used, for example, for automotive lighting, heads up display (HUD) lighting, horticultural lighting, street lighting, torch for video, general illumination (e.g., home, shop, office and studio lighting, theater/stage lighting and architectural lighting), augmented reality (AR) lighting, virtual reality (VR) lighting, as back lights for displays, and IR spectroscopy. A single LED may provide light that is less bright than an incandescent light source, and, therefore, multi-junction devices or arrays of LEDs (such as monolithic LED arrays, micro LED arrays, etc.) may be used for applications where more brightness is desired or required.

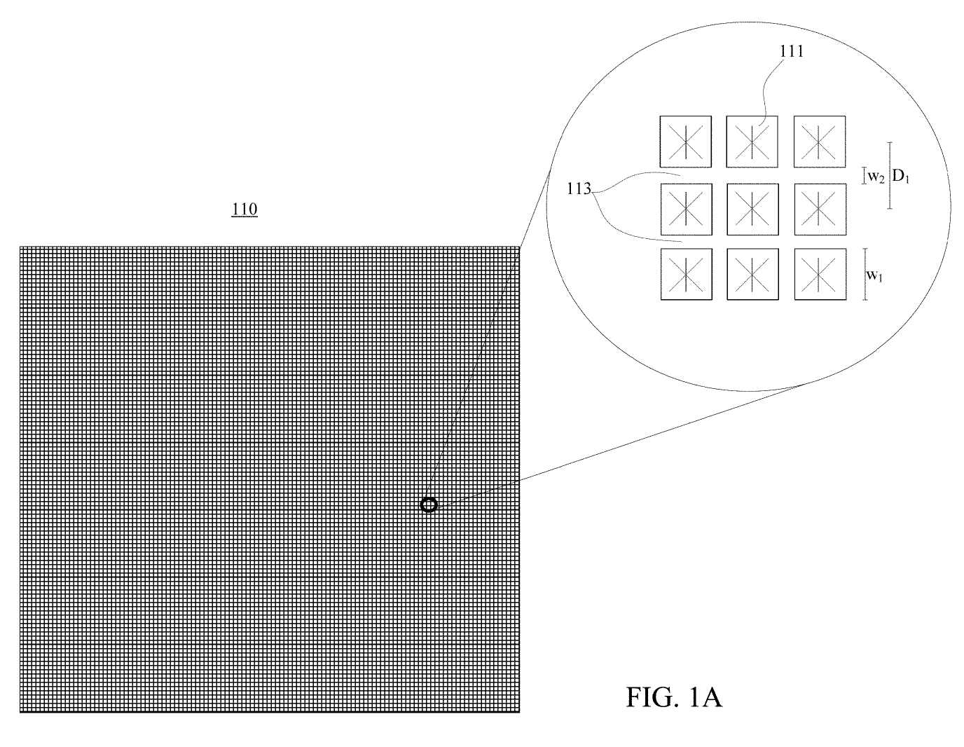

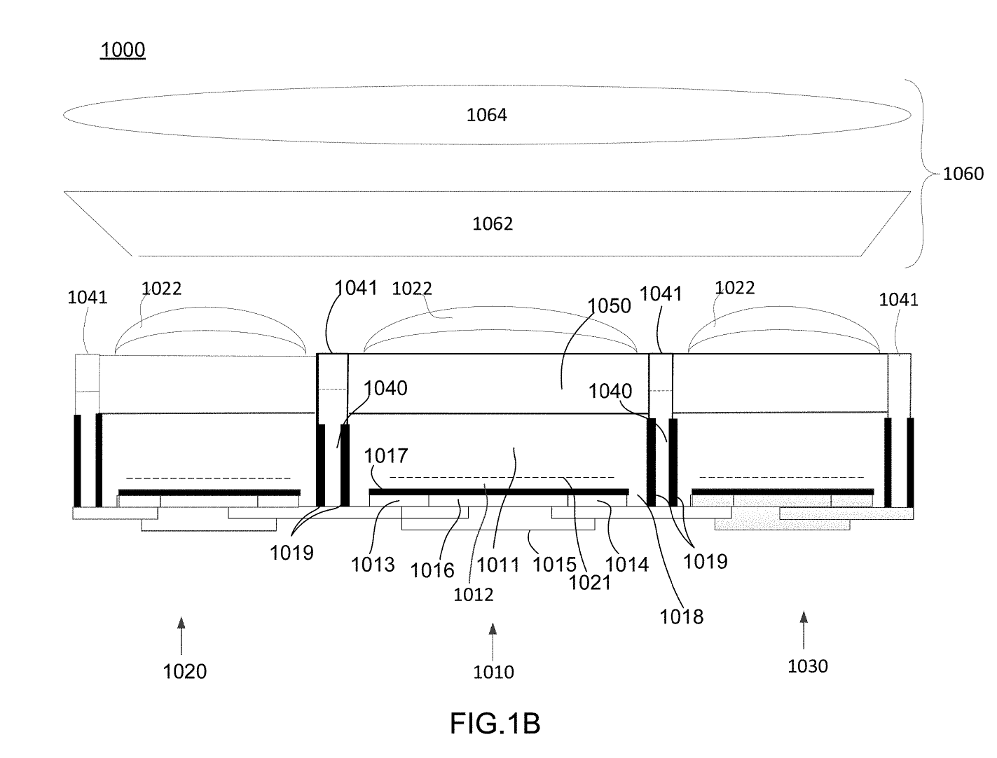

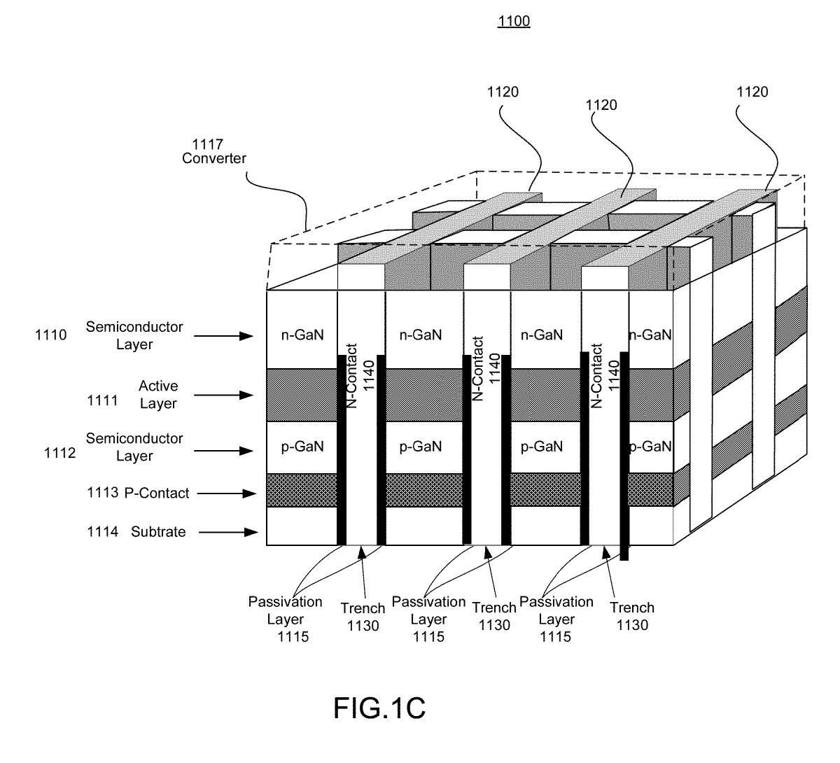

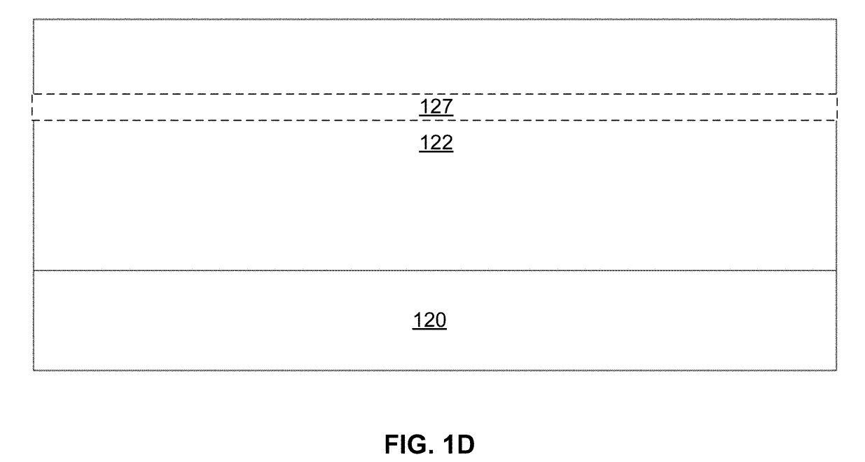

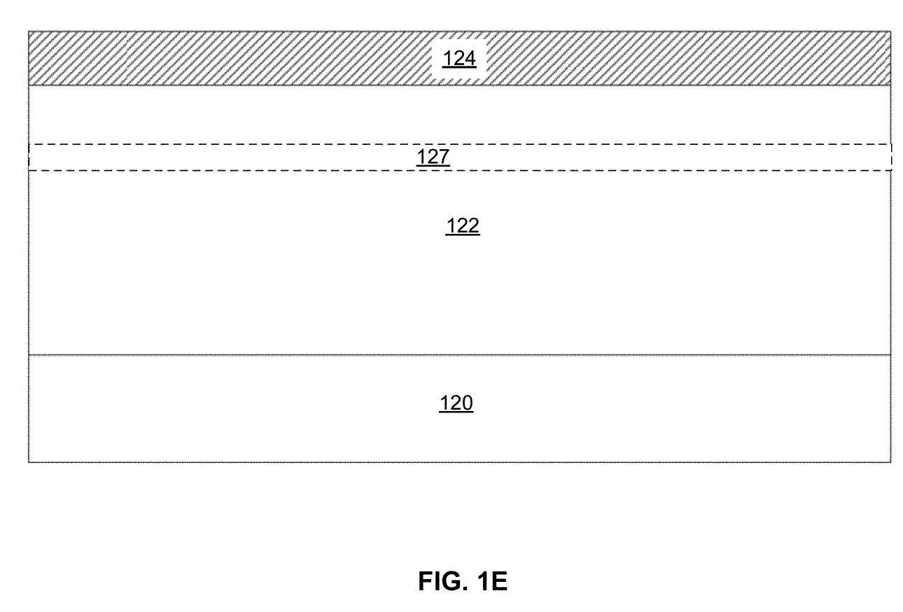

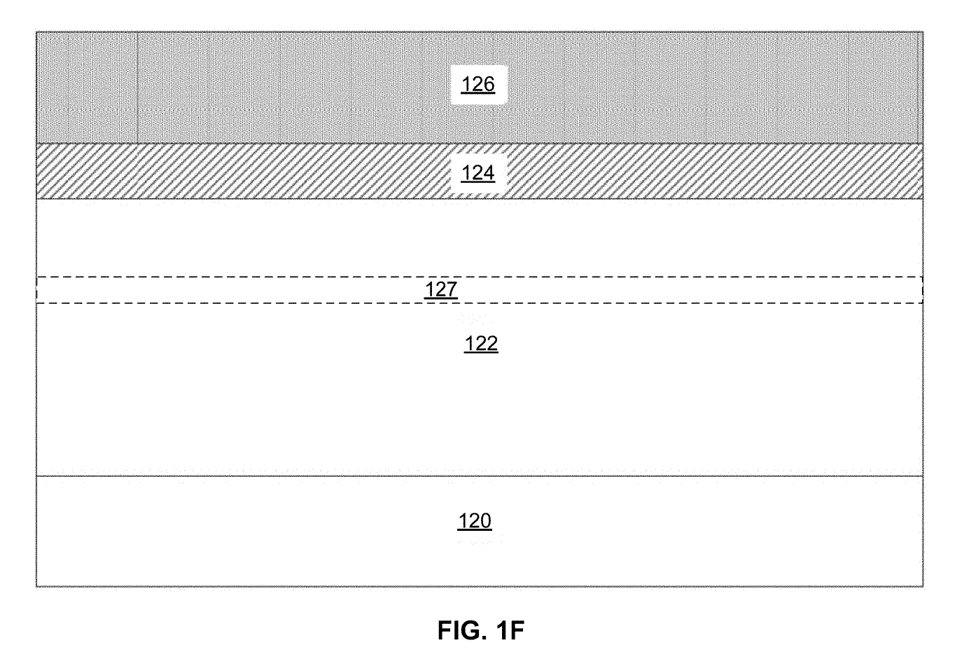

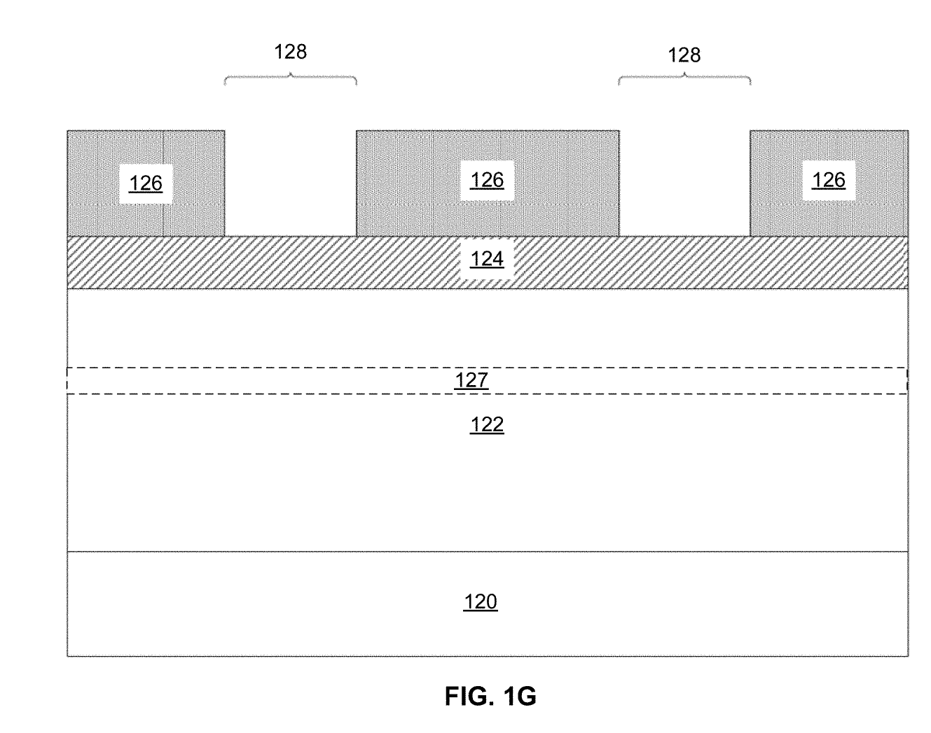

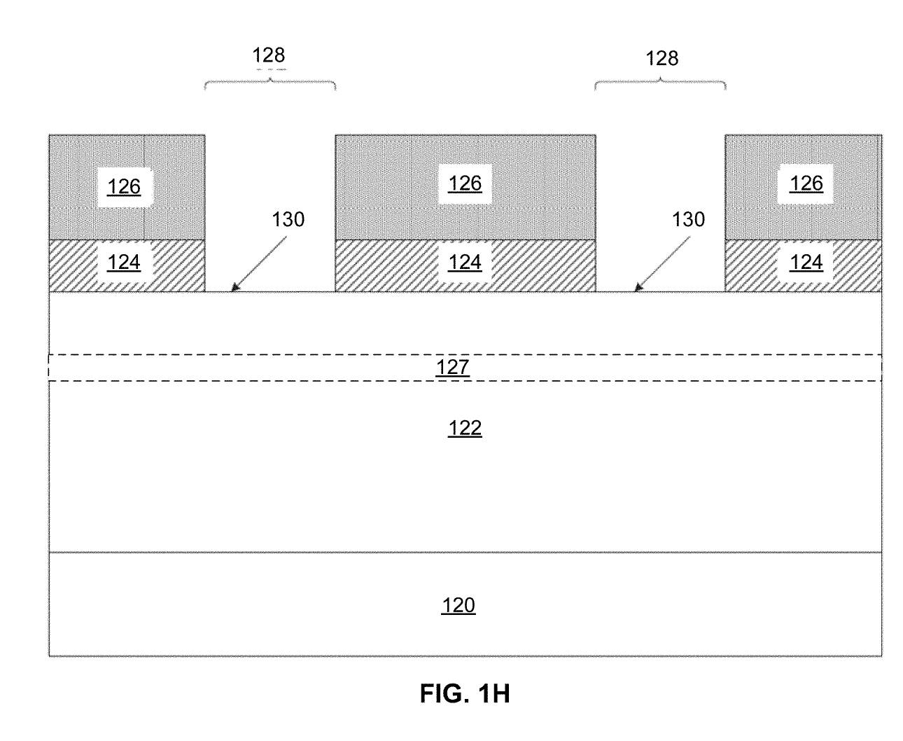

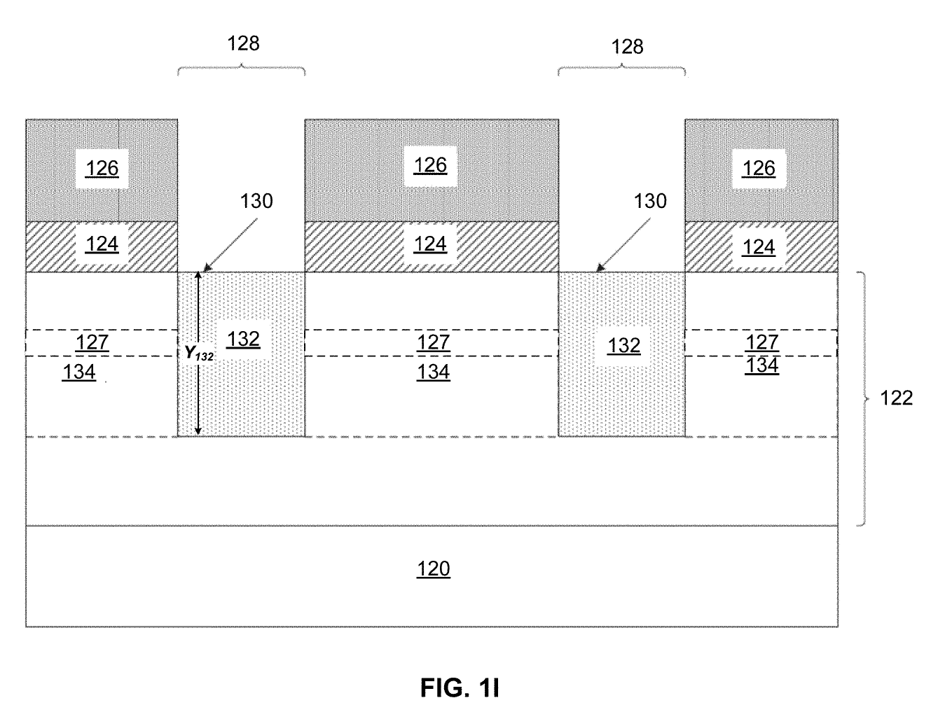

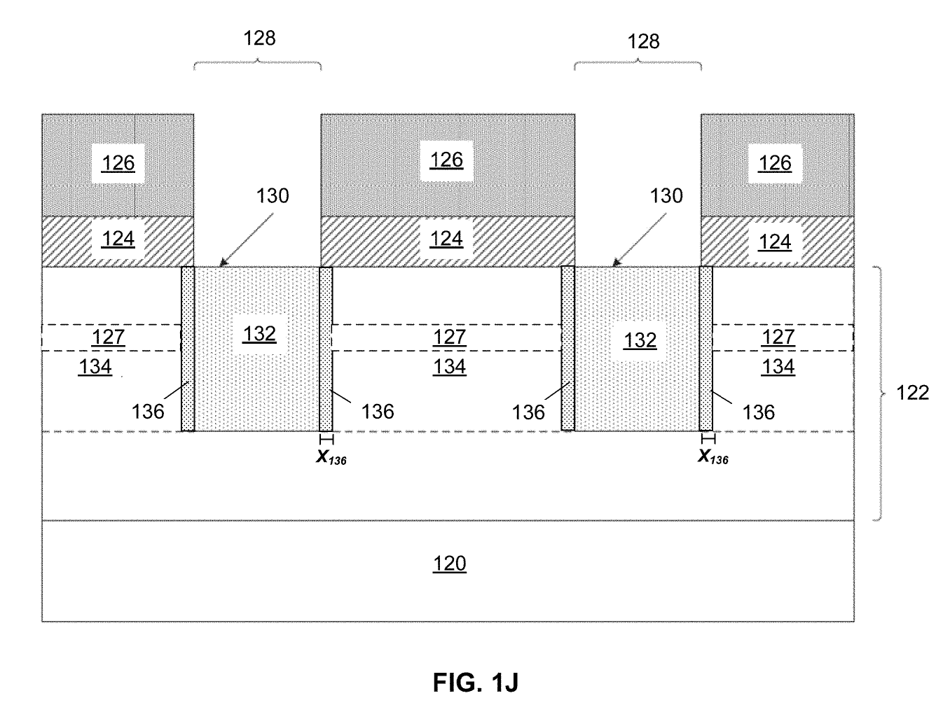

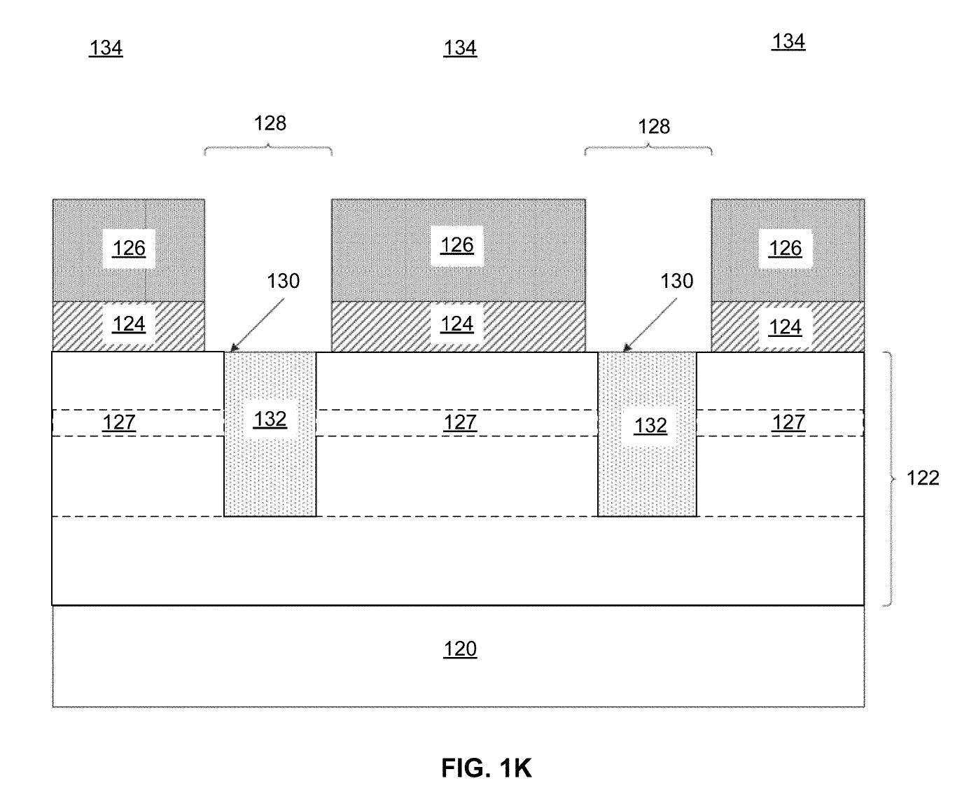

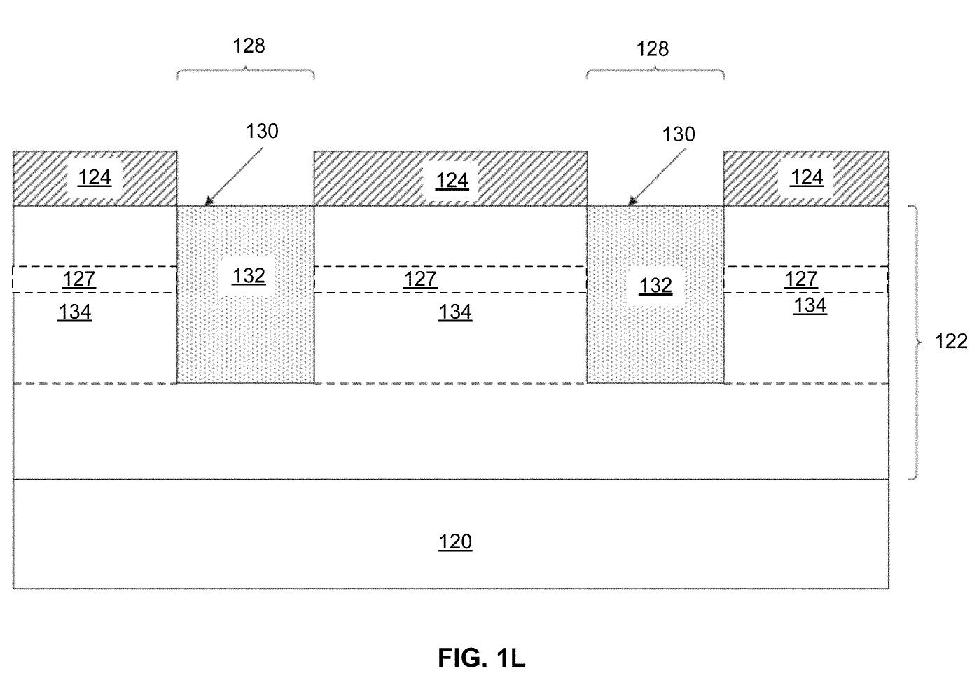

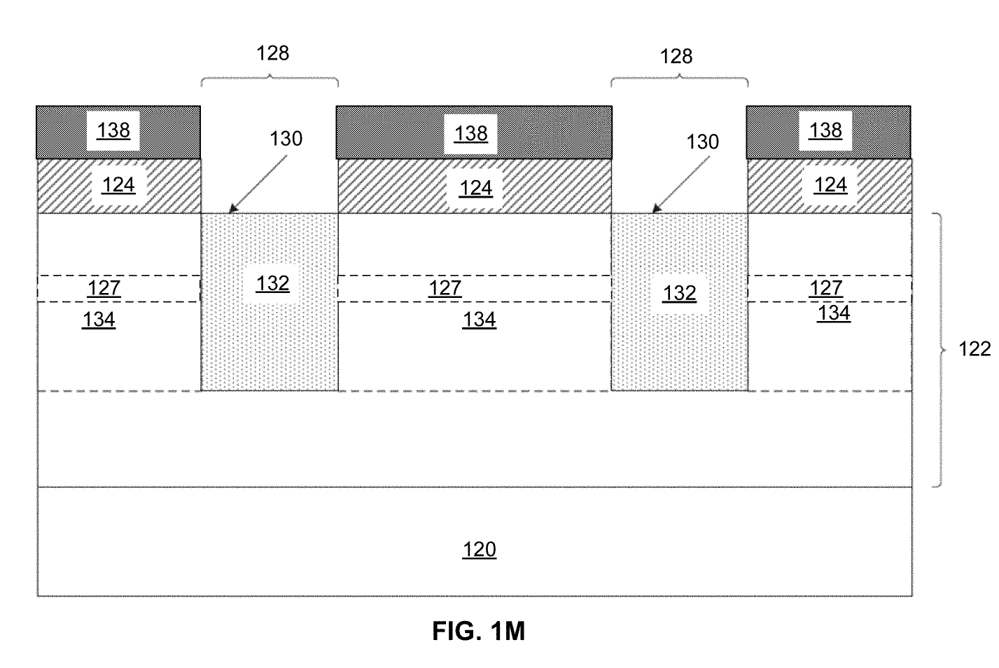

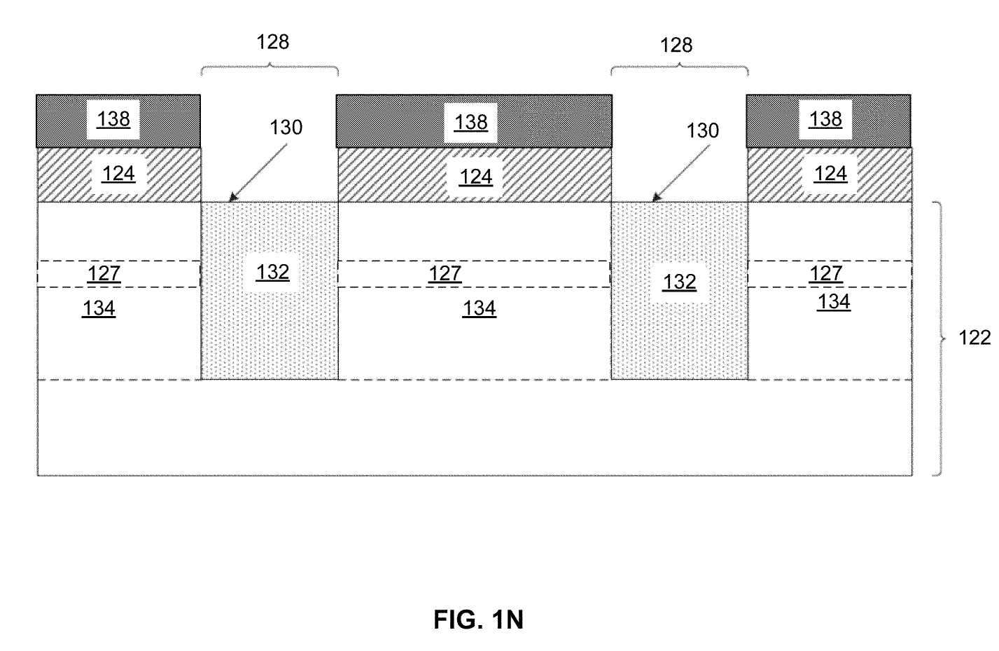

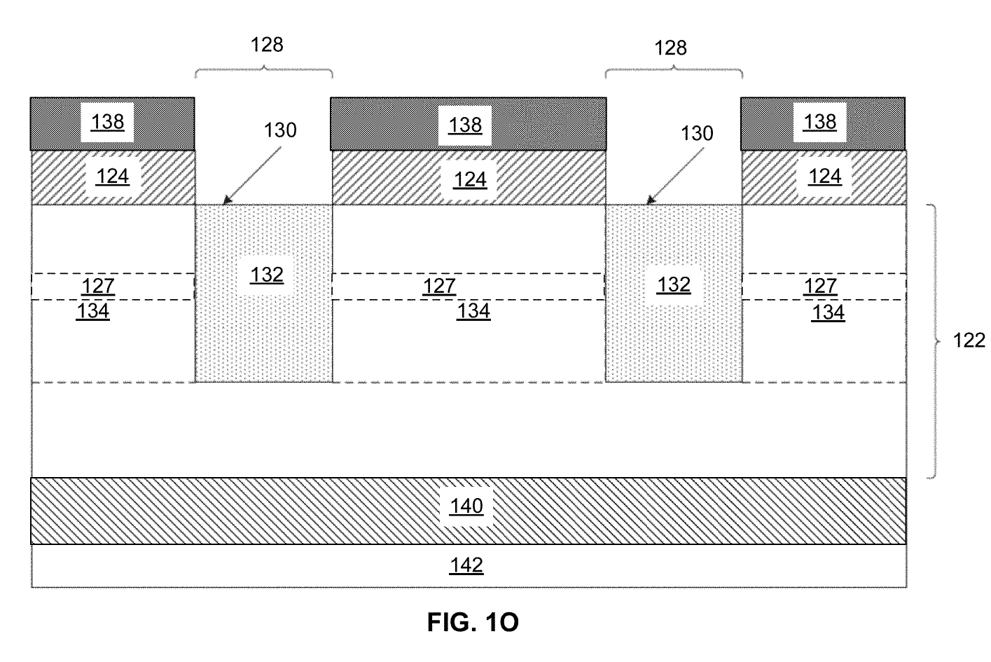

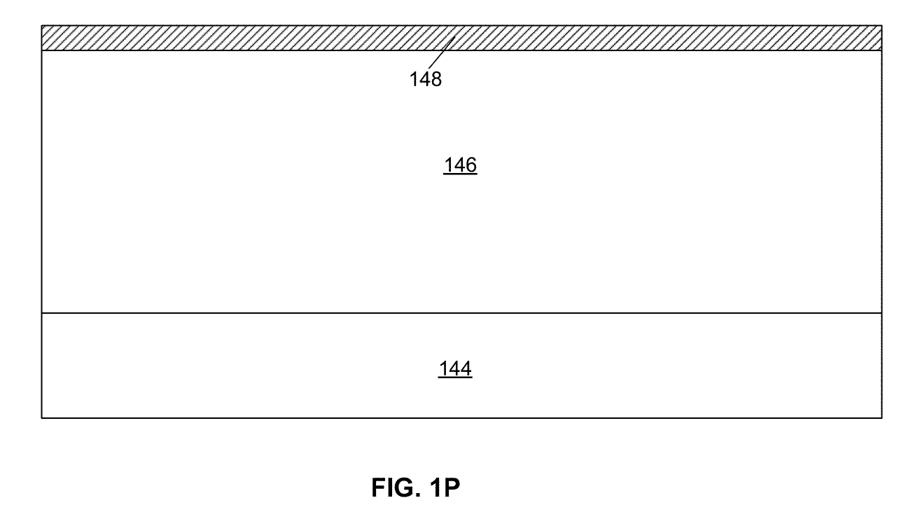

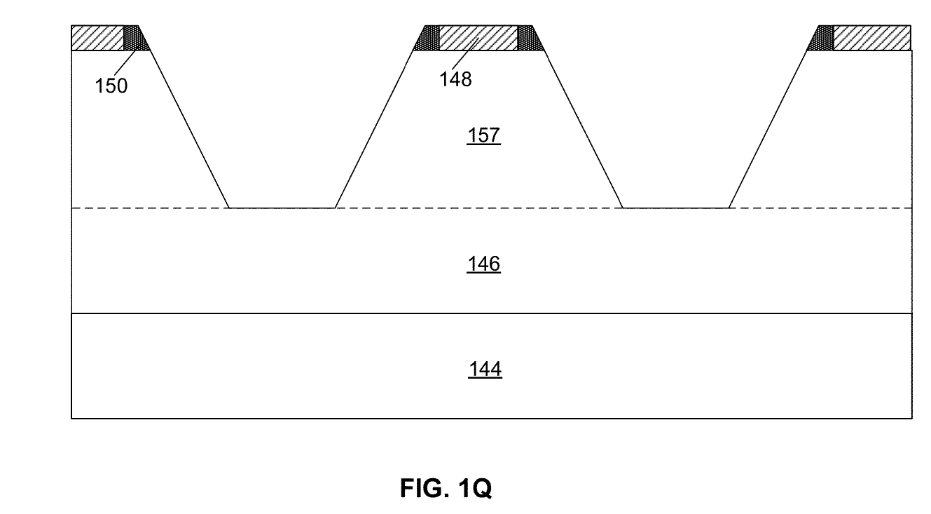

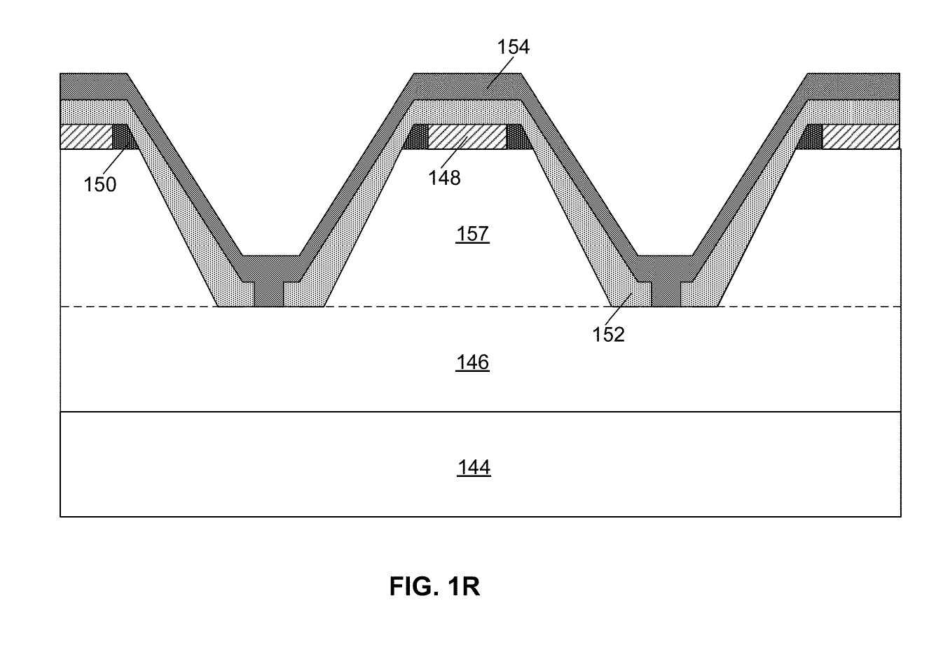

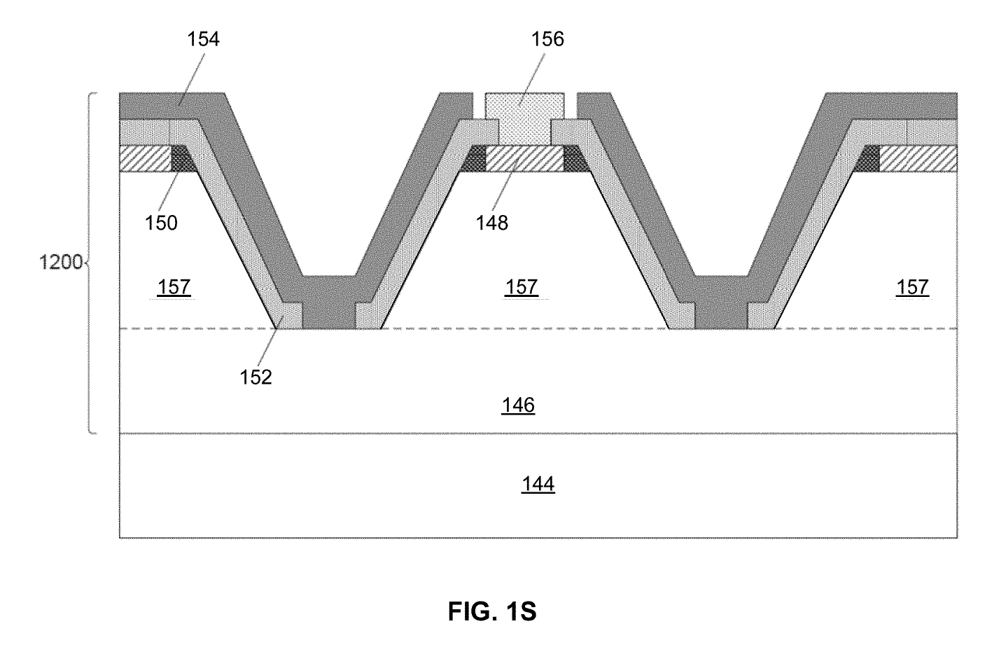

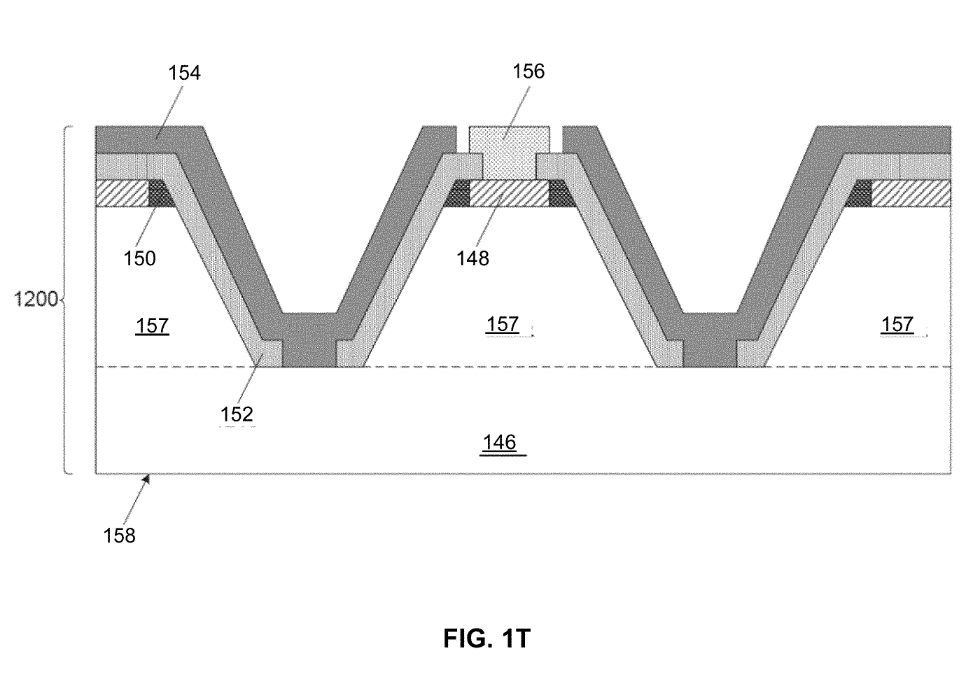

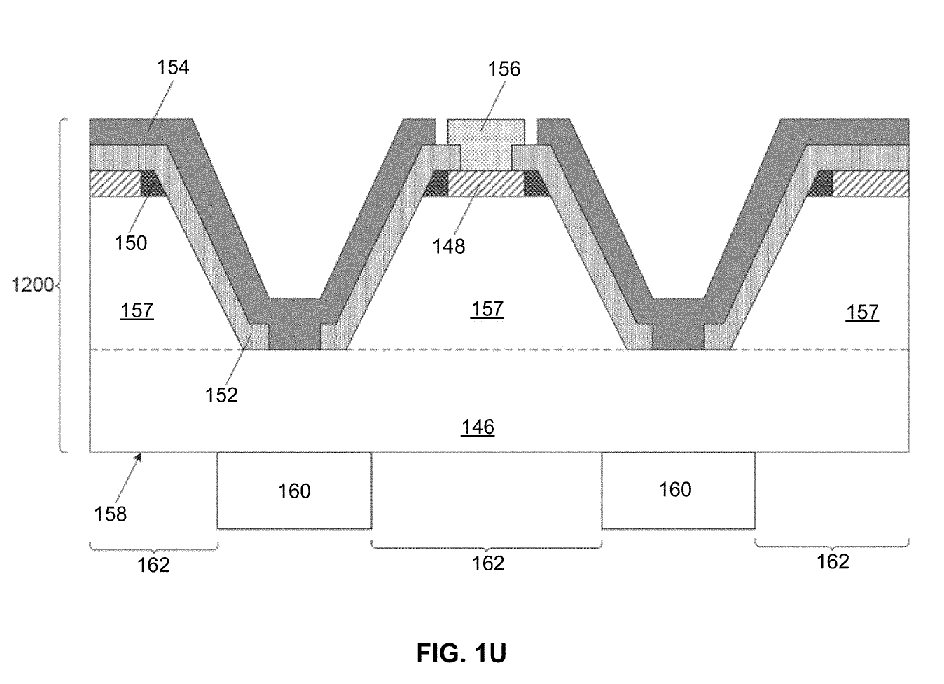

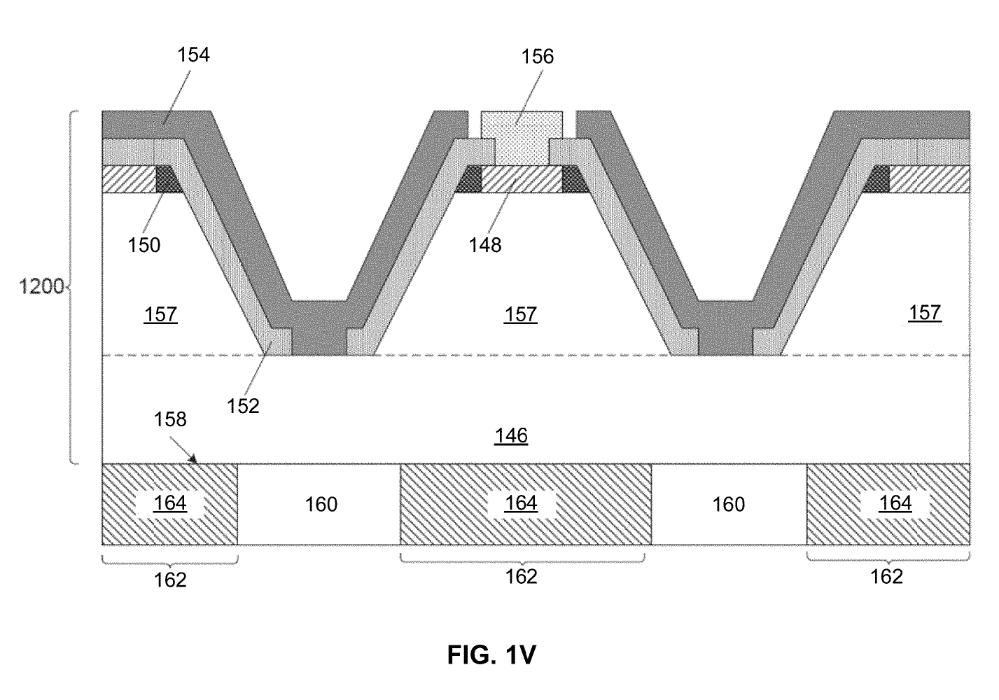

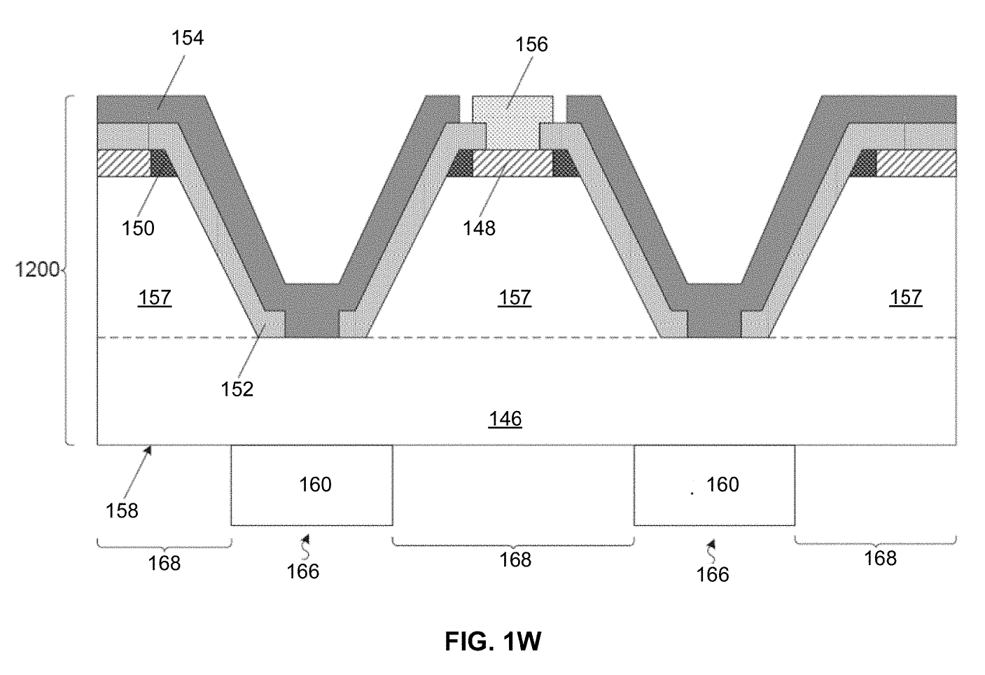

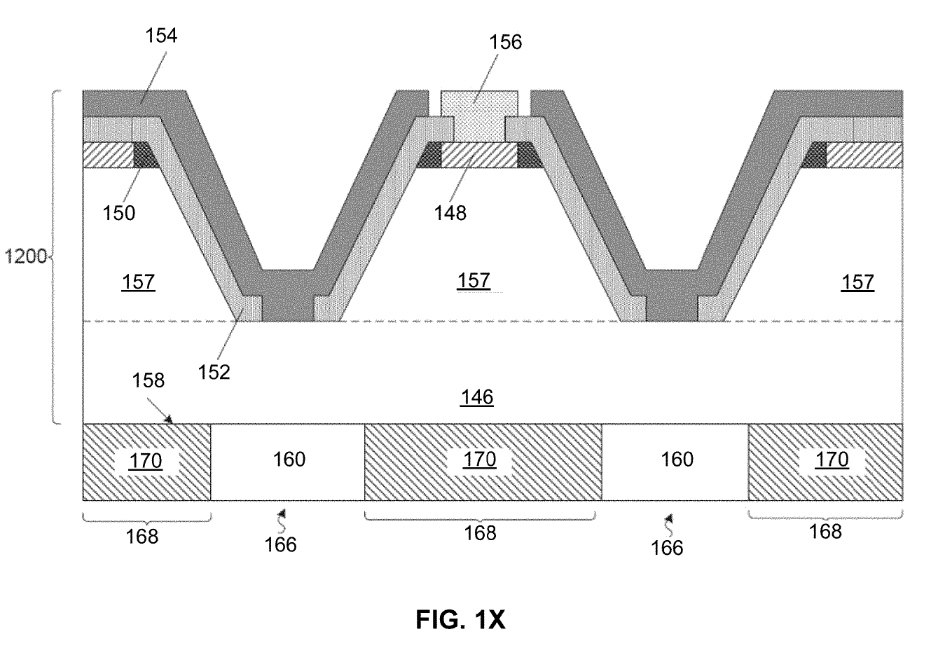

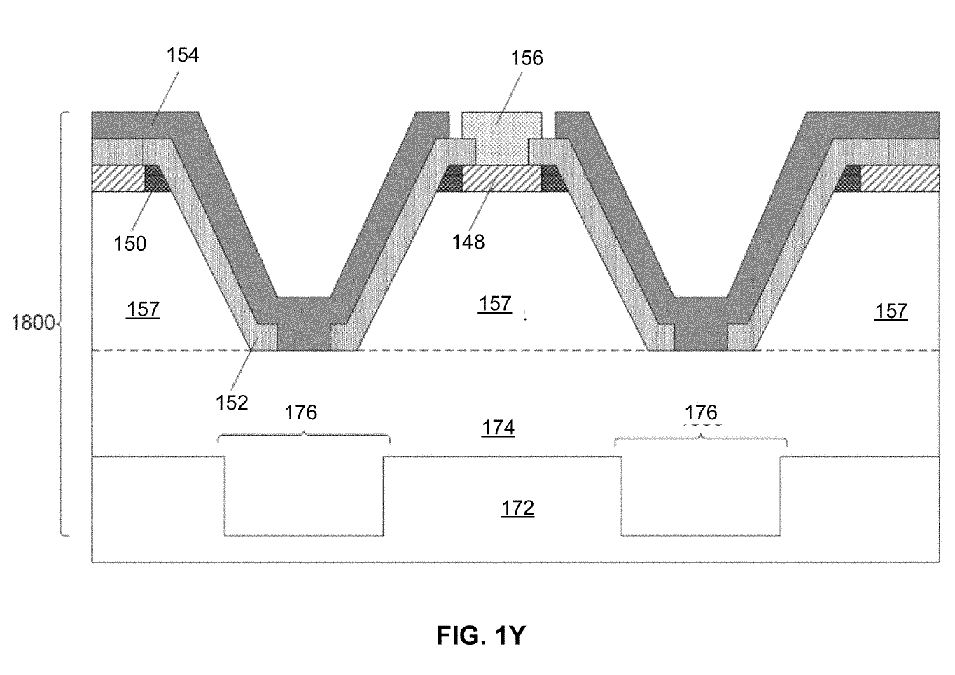

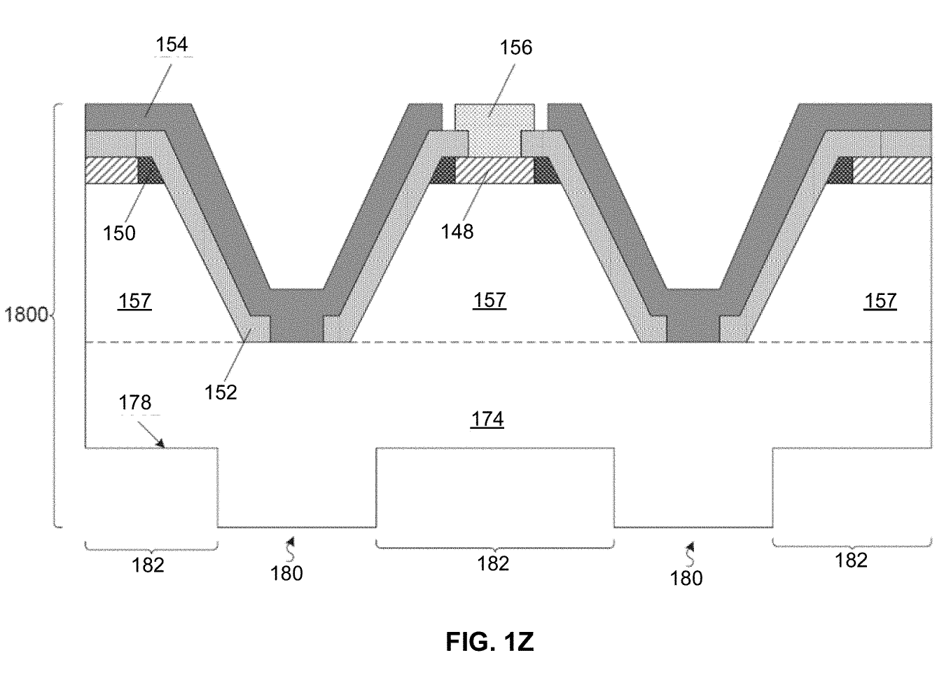

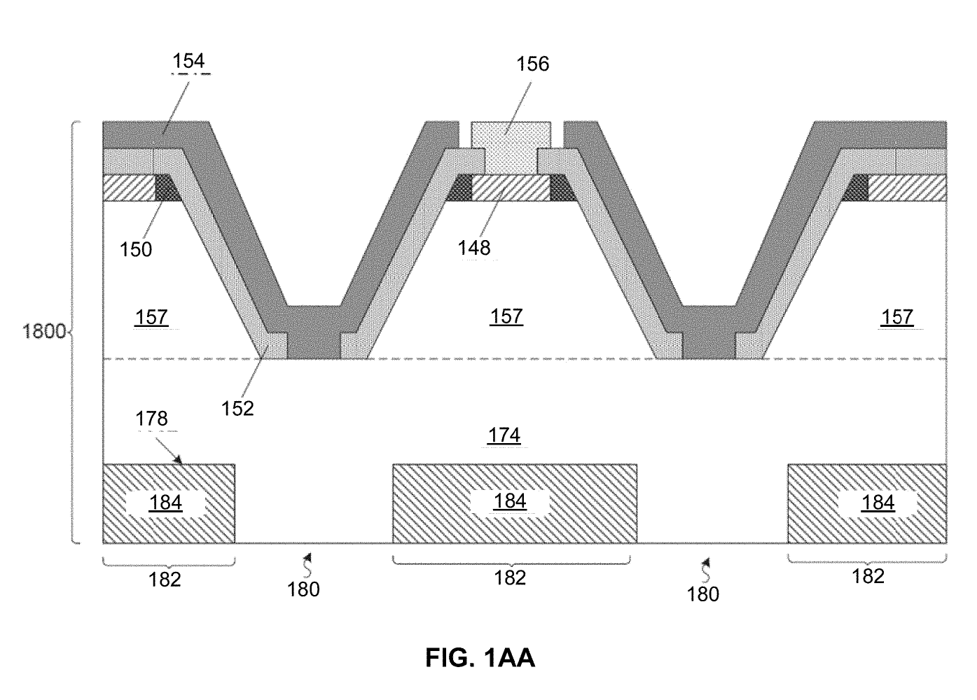

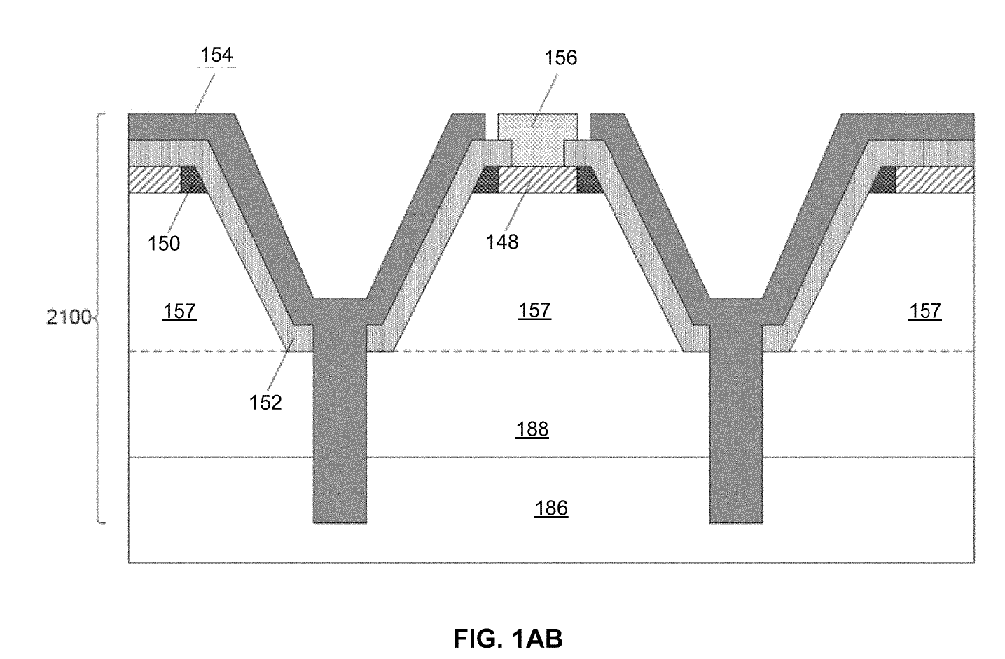

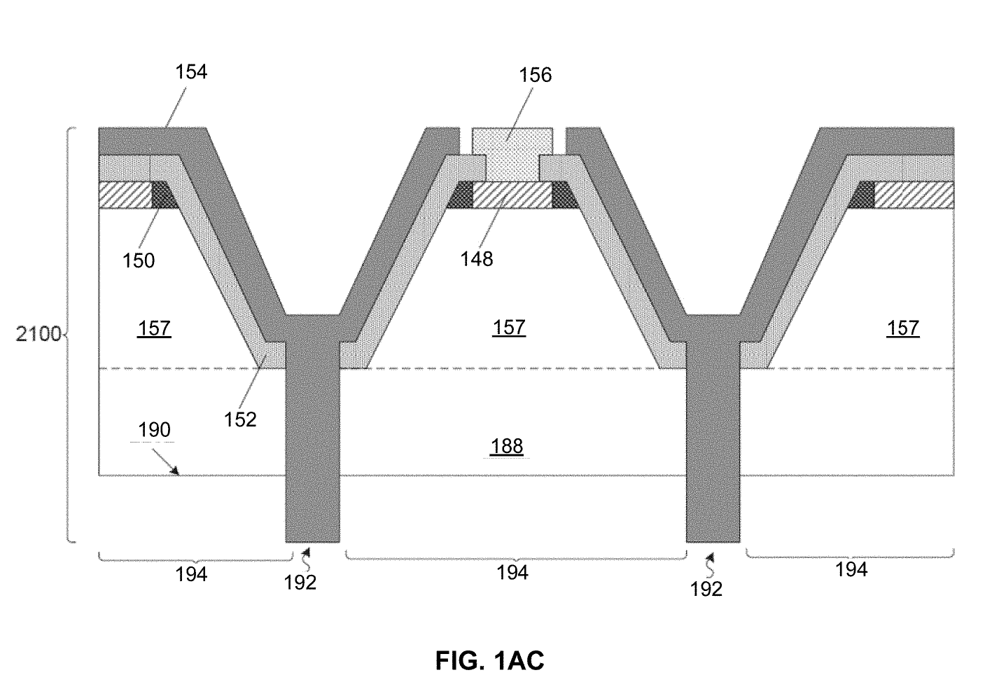

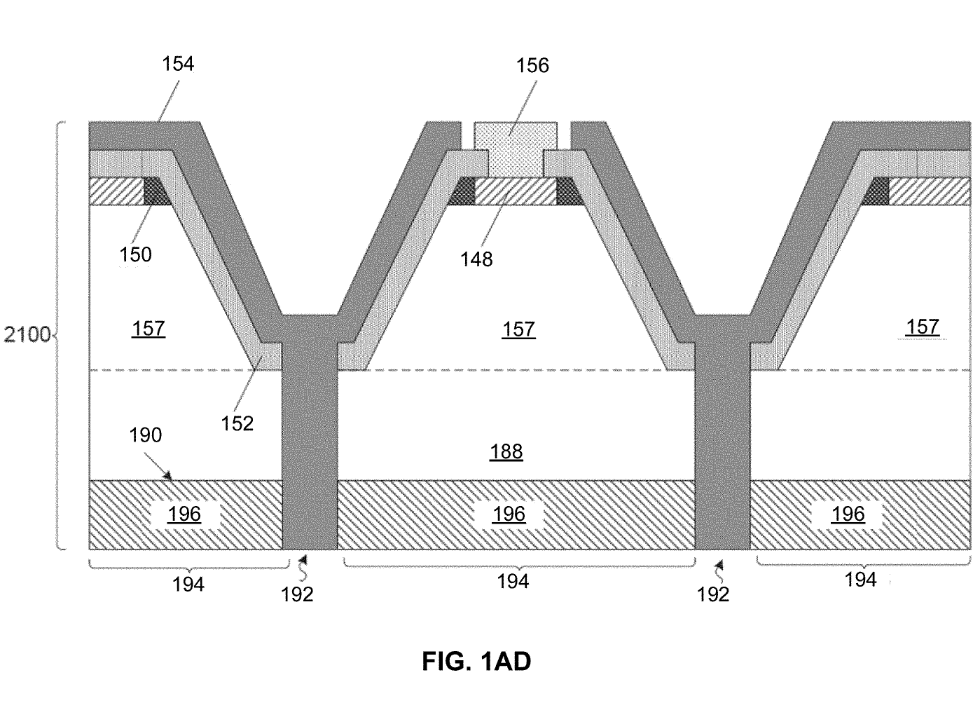

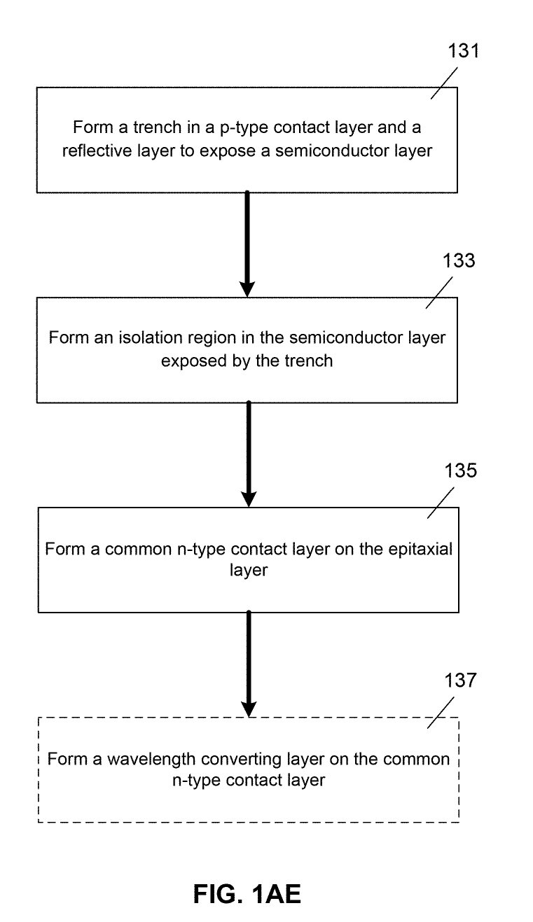

According to embodiments of the disclosed subject matter, LED arrays (e.g., micro LED arrays) may include an array of pixels as shown in FIG. 1A, 1B, and/or 1C. LED arrays may be used for any applications such as those requiring precision control of LED array segments. Pixels in an LED array may be individually addressable, may be addressable in groups/subsets, or may not be addressable. In FIG. 1A, a top view of a LED array 110 with pixels 111 is shown. An exploded view of a 3×3 portion of the LED array 110 is also shown in FIG. 1A. As shown in the 3×3 portion exploded view, LED array 110 may include pixels 111 with a width w₁ of approximately 100 μm or less (e.g., 40 μm). The lanes 113 between the pixels may be separated by a width, w₂, of approximately 20 μm or less (e.g., 5 μm). The lanes 113 may provide an air gap between pixels or may contain other material, as shown in FIGS. 1B and 10 and further disclosed herein. The distance d₁ from the center of one pixel 111 to the center of an adjacent pixel 111 may be approximately 120 μm or less (e.g., 45 μm). It will be understood that the widths and distances provided herein are examples only, and that actual widths and/or dimensions may vary.

It will be understood that although rectangular pixels arranged in a symmetric matrix are shown in FIGS. 1A, B and C, pixels of any shape and arrangement may be applied to the embodiments disclosed herein. For example, LED array 110 of FIG. 1A may include, over 10,000 pixels in any applicable arrangement such as a 100×100 matrix, a 200×50 matrix, a symmetric matrix, a non-symmetric matrix, or the like. It will also be understood that multiple sets of pixels, matrixes, and/or boards may be arranged in any applicable format to implement the embodiments disclosed herein.

FIG. 1B shows a cross section view of an example LED array 1000. As shown, the pixels 1010, 1020, and 1030 correspond to three different pixels within an LED array such that a separation sections 1041 and/or n-type contacts 1040 separate the pixels from each other. According to an embodiment, the space between pixels may be occupied by an air gap. As shown, pixel 1010 includes an epitaxial layer 1011 which may be grown on any applicable substrate such as, for example, a sapphire substrate, which may be removed from the epitaxial layer 1011. A surface of the growth layer distal from contact 1015 may be substantially planar or may be patterned. A p-type region 1012 may be located in proximity to a p-contact 1017. An active region 1021 may be disposed adjacent to the n-type region and a p-type region 1012. Alternatively, the active region 1021 may be between a semiconductor layer or n-type region and p-type region 1012 and may receive a current such that the active region 1021 emits light beams. The p-contact 1017 may be in contact with SiO2 layers 1013 and 1014 as well as plated metal (e.g., plated copper) layer 1016. The n type contacts 1040 may include an applicable metal such as Cu. The metal layer 1016 may be in contact with a reflective layer 1015 which may serve as a contact.

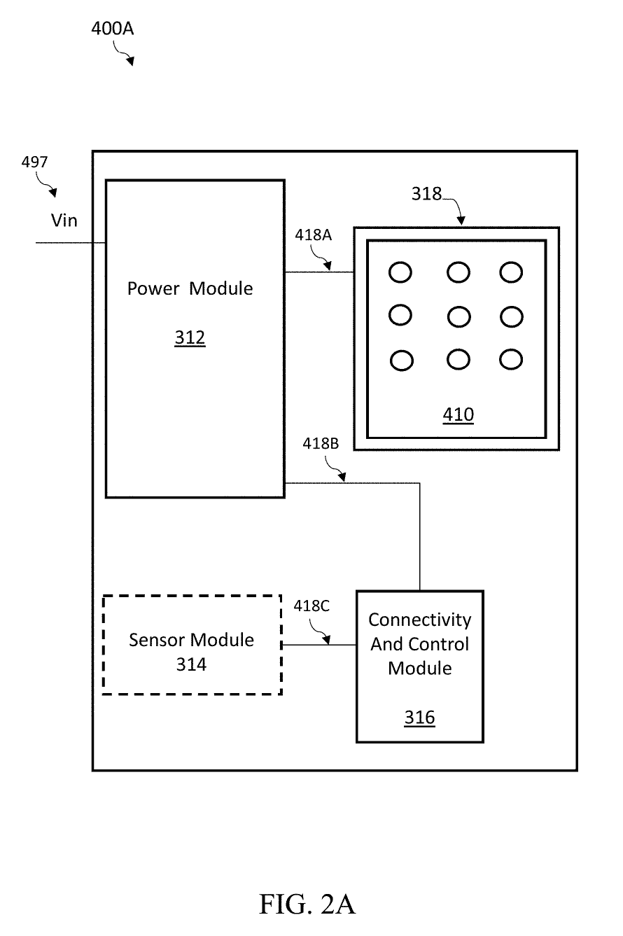

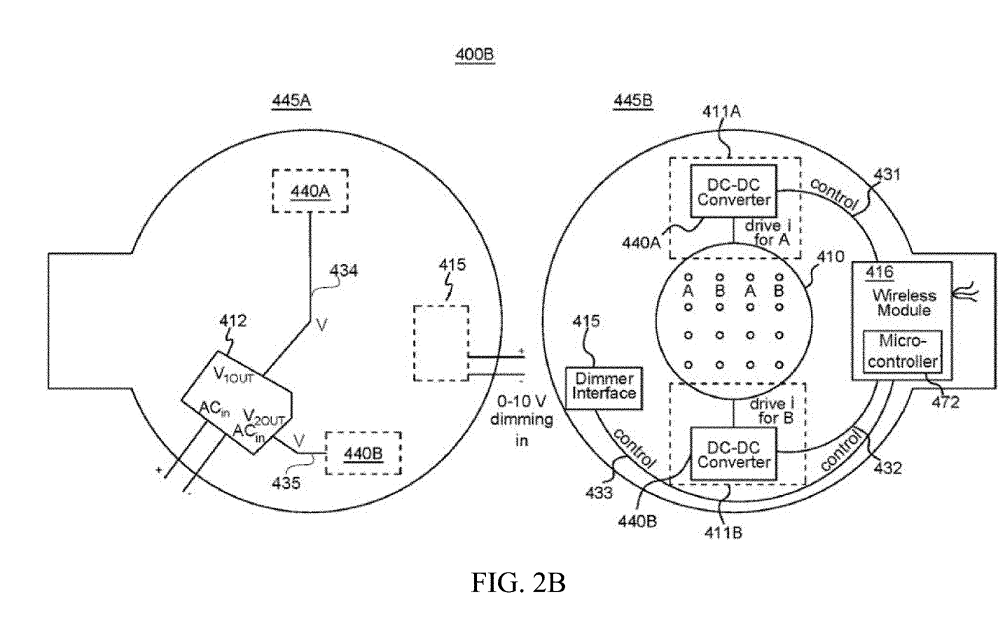

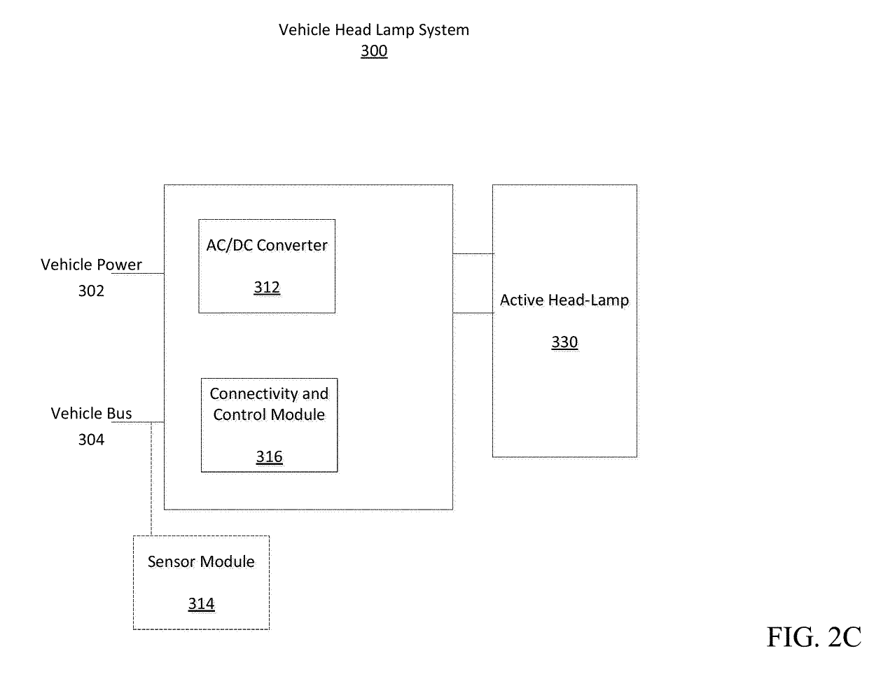

Notably, as shown in FIG. 1B, the n-type contact 1040 may be deposited into trenches 1130 created between pixels 1010, 1020, and 1030 and may extend beyond the epitaxial layer. Separation sections 1041 may separate all (as shown) or part of a converter material 1050. It will be understood that a LED array may be implemented without such separation sections 1041 or the separation sections 1041 may correspond to an air gap. The separation sections 1041 may be an extension of the n-type contacts 1040, such that, separation sections 1041 are formed from the same material as the n-type contacts 1040 (e.g., copper). Alternatively, the separation sections 1041 may be formed from a material different than the n-type contacts 1040. According to an embodiment, separation sections 1041 may include reflective material. The material in separation sections 1041 and/or the n-type contact 1040 may be deposited in any applicable manner such as, for example, but applying a mesh structure which includes or allows the deposition of the n-type contact 1040 and/or separation sections 1041. Converter material 1050 may have features/properties similar to wavelength converting layer 205 of FIG. 2A. As noted herein, one or more additional layers may coat the separation sections 1041. Such a layer may be a reflective layer, a scattering layer, an absorptive layer, or any other applicable layer. One or more passivation layers 1019 may fully or partially separate the n-contact 1040 from the epitaxial layer 1011.

The epitaxial layer 1011 may be formed from any applicable material to emit photons when excited including sapphire, SiC, GaN, Silicone and may more specifically be formed from a III-V semiconductors including, but not limited to, AlN, AlP, AlAs, AlSb, GaN, GaP, GaAs, GaSb, InN, InP, InAs, InSb, II-VI semiconductors including, but not limited to, ZnS, ZnSe, CdSe, CdTe, group IV semiconductors including, but not limited to Ge, Si, SiC, and mixtures or alloys thereof. These example semiconductors may have indices of refraction ranging from about 2.4 to about 4.1 at the typical emission wavelengths of LEDs in which they are present. For example, III-Nitride semiconductors, such as GaN, may have refractive indices of about 2.4 at 500 nm, and III-Phosphide semiconductors, such as InGaP, may have refractive indices of about 3.7 at 600 nm. Contacts coupled to the LED device 200 may be formed from a solder, such as AuSn, AuGa, AuSi or SAC solders.

The n-type region may be grown on a growth substrate and may include one or more layers of semiconductor material that include different compositions and dopant concentrations including, for example, preparation layers, such as buffer or nucleation layers, and/or layers designed to facilitate removal of the growth substrate. These layers may be n-type or not intentionally doped, or may even be p-type device layers. The layers may be designed for particular optical, material, or electrical properties desirable for the light emitting region to efficiently emit light. Similarly, the p-type region 1012 may include multiple layers of different composition, thickness, and dopant concentrations, including layers that are not intentionally doped, or n-type layers. An electrical current may be caused to flow through the p-n junction (e.g., via contacts) and the pixels may generate light of a first wavelength determined at least in part by the bandgap energy of the materials. A pixel may directly emit light (e.g., regular or direct emission LED) or may emit light into a wavelength converting layer 1050 (e.g., phosphor converted LED, “POLED”, etc.) that acts to further modify wavelength of the emitted light to output a light of a second wavelength.

Although FIG. 1B shows an example LED array 1000 with pixels 1010, 1020, and 1030 in an example arrangement, it will be understood that pixels in an LED array may be provided in any one of a number of arrangements. For example, the pixels may be in a flip chip structure, a vertical injection thin film (VTF) structure, a multi-junction structure, a thin film flip chip (TFFC), lateral devices, etc. For example, a lateral LED pixel may be similar to a flip chip LED pixel but may not be flipped upside down for direct connection of the electrodes to a substrate or package. A TFFC may also be similar to a flip chip LED pixel but may have the growth substrate removed (leaving the thin film semiconductor layers un-supported). In contrast, the growth substrate or other substrate may be included as part of a flip chip LED.

The wavelength converting layer 1050 may be in the path of light emitted by active region 1021, such that the light emitted by active region 1021 may traverse through one or more intermediate layers (e.g., a photonic layer). According to embodiments, wavelength converting layer 1050 or may not be present in LED array 1000. The wavelength converting layer 1050 may include any luminescent material, such as, for example, phosphor particles in a transparent or translucent binder or matrix, or a ceramic phosphor element, which absorbs light of one wavelength and emits light of a different wavelength. The thickness of a wavelength converting layer 1050 may be determined based on the material used or application/wavelength for which the LED array 1000 or individual pixels 1010, 1020, and 1030 is/are arranged. For example, a wavelength converting layer 1050 may be approximately 20 μm, 50 μm or 200 μm. The wavelength converting layer 1050 may be provided on each individual pixel, as shown, or may be placed over an entire LED array 1000.

Primary optic 1022 may be on or over one or more pixels 1010, 1020, and/or 1030 and may allow light to pass from the active region 101 and/or the wavelength converting layer 1050 through the primary optic. Light via the primary optic may generally be emitted based on a Lambertian distribution pattern such that the luminous intensity of the light emitted via the primary optic 1022, when observed from an ideal diffuse radiator, is directly proportional to the cosine of the angle between the direction of the incident light and the surface normal. It will be understood that one or more properties of the primary optic 1022 may be modified to produce a light distribution pattern that is different than the Lambertian distribution pattern.

Secondary optics which include one or both of the lens 1065 and waveguide 1062 may be provided with pixels 1010, 1020, and/or 1030. It will be understood that although secondary optics are discussed in accordance with the example shown in FIG. 1B with multiple pixels, secondary optics may be provided for single pixels. Secondary optics may be used to spread the incoming light (diverging optics), or to gather incoming light into a collimated beam (collimating optics). The waveguide 1062 may be coated with a dielectric material, a metallization layer, or the like and may be provided to reflect or redirect incident light. In alternative embodiments, a lighting system may not include one or more of the following: the wavelength converting layer 1050, the primary optics 1022, the waveguide 1062 and the lens 1065.

Lens 1065 may be formed form any applicable transparent material such as, but not limited to SiC, aluminum oxide, diamond, or the like or a combination thereof. Lens 1065 may be used to modify the a beam of light to be input into the lens 1065 such that an output beam from the lens 1065 will efficiently meet a desired photometric specification. Additionally, lens 1065 may serve one or more aesthetic purpose, such as by determining a lit and/or unlit appearance of the multiple LED devices 200B.

FIG. 1C shows a cross section of a three dimensional view of a LED array 1100. As shown, pixels in the LED array 1100 may be separated by trenches which are filled to form n-contacts 1140. The pixels may be grown on a substrate 1114 and may include a p-contact 1113, a p-GaN semiconductor layer 1112, an active region 1111, and an n-Gan semiconductor layer 1110. It will be understood that this structure is provided as an example only and one or more semiconductor or other applicable layers may be added, removed, or partially added or removed to implement the disclosure provided herein. A converter material 1117 may be deposited on the semiconductor layer 1110 (or other applicable layer).

Passivation layers 1115 may be formed within the trenches 1130 and n-contacts 1140 (e.g., copper contacts) may be deposited within the trenches 1130, as shown. The passivation layers 1115 may separate at least a portion of the n-contacts 1140 from one or more layers of the semiconductor. According to an implementation, the n-contacts 1140, or other applicable material, within the trenches may extend into the converter material 1117 such that the n-contacts 1140, or other applicable material, provide complete or partial optical isolation between the pixels.

One approach for electrical isolation may include selective ion implants. For example, ions may be implanted in a pattern that defines an implanted perimeter around an LED die. With sufficient doping, the implanted ions may be highly resistive and may isolate or define a junction of the implanted perimeter. One approach for providing electrical connections may include transparent conductors. For example, transparent conductors may be used in a conventional, non-monolithic LED structure that sandwiches a light active material with transparent conductors such as indium tin oxide (ITO).

Monolithic segmented LEDs constructed using etched gallium nitride (GaN) mesas is feasible, but has substantial associated processing costs. Elimination of the etched mesa would reduce edge losses and provide for a more mechanically sound device. The following description includes methods of using selective ion implantation and transparent conductors to form monolithic segmented LEDs without the need for etched individual mesas. Apparatuses described herein may include sub-100 μm to 300 μm pixels separated by electrically non-conductive lanes having a width less than approximately 50 μm. The electrical isolation between pixels on a monolithic substrate may be provided by ion implantation into a GaN layer. A common n-contact for the pixels may be provided by a transparent conductor layer. A sapphire substrate may be removed to reduce lateral light transfer.

Referring now to FIG. 1D, a cross section view of an epitaxial layer 122 formed on a sapphire substrate 120 is shown. The sapphire substrate 120 may compose a crystalline material, such as aluminum oxide, and may be a commercial sapphire wafer. The epitaxial layer 122 may compose any Group III-V semiconductors, including binary, ternary, and quaternary alloys of gallium, aluminum, indium, and nitrogen, also referred to as III-nitride materials. In an example, the epitaxial layer 122 may compose GaN. The epitaxial layer 122 may be formed using conventional deposition techniques, such as metal-organic chemical vapor deposition (MOCVD), molecular beam epitaxy (MBE), or other epitaxial techniques. In an epitaxial deposition process, chemical reactants provided by one or more source gases are controlled and the system parameters are set so that depositing atoms arrive at a deposition surface with sufficient energy to move around on the surface and orient themselves to the crystal arrangement of the atoms of the deposition surface. Accordingly, the epitaxial layer 122 may be grown on the sapphire substrate 120 using conventional epitaxial techniques.

The epitaxial layer 122 may be similar to the epitaxial layer 1011 described above with reference to FIG. 1B and may be formed using similar techniques. As described above, the epitaxial layer may include an active region 127 between a first semiconductor layer and a second semiconductor layer. The active region 127 may be composed of any Group III-V semiconductors, including binary, ternary, and quaternary alloys of gallium, aluminum, indium, and nitrogen, also referred to as III-nitride materials. For example, the active region 127 may be composed of III-V semiconductors including but not limited to AN, AlP, AlAs, AlSb, GaN, GaP, GaAs, GaSb, InN, InP, InAs, InSb, II-VI semiconductors including but not limited to ZnS, ZnSe, CdSe, CdTe, group IV semiconductors including but not limited to Ge, Si, SiC, and mixtures or alloys thereof. These semiconductors may have indices of refraction ranging from about 2.4 to about 4.1 at the typical emission wavelengths of LEDs in which they are present. For example, III-nitride semiconductors, such as GaN, may have refractive indices of about 2.4 at 500 nm, and III-phosphide semiconductors, such as InGaP, may have refractive indices of about 3.7 at 600 nm. In an example, the second semiconductor layer 130 and the active region 128 may be composed of GaN.

Referring now to FIG. 1E, a cross section view illustrating forming a reflective layer 124 on the epitaxial layer 122 is shown. The reflective layer 124 may compose any material that reflects visible light, such as, for example, a refractive metal. The reflective layer 124 may compose one or more of a metal such as silver, gold, and titanium oxide, a metal stack, a dielectric material, or combinations thereof. The reflective layer 124 may be formed using a conventional deposition technique, such as, for example, chemical vapor deposition (CVD), plasma-enhanced CVD (PECVD), metal organic chemical vapor deposition (MOCVD), atomic layer deposition (ALD), evaporation, reactive sputtering, chemical solution deposition, spin-on deposition, or other like processes.

Referring now to FIG. 1F, a cross section view illustrating forming a resist layer 126 on the reflective layer 124 is shown. The resist layer 126 may compose a conventional photoresist material based on photoacid accelerators, such as, for example, a negative tone or a positive tone resist. A positive tone resist is a type of photoresist in which the portion of the photoresist that is exposed to light becomes soluble to the photoresist developer. The portion of the photoresist that is unexposed remains insoluble to the photoresist developer. A negative tone resist is a type of photoresist in which the portion of the photoresist that is exposed to light becomes insoluble to the photoresist developer. The unexposed portion of the photoresist is dissolved by the photoresist developer. The resist layer 126 may compose a conventional x-ray resist material. The resist layer 126 may include an anti-reflection coating (ARC) layer (not shown) first deposited on the reflective layer 124. The ARC layer may compose a conventional ARC material.

Referring now to FIG. 1G, a cross section view illustrating patterning the resist layer 126 to form one or more trenches 128 is shown. The resist layer 126 may be masked and exposed to an energy source to remove a portion of the resist layer 126 and form the one or more trenches 128. A patterning mask with an opaque region and a transparent region may be formed on the resist layer 126 and may be illuminated by the energy source. The energy source may pass through the transparent region. In a positive tone photoresist, this may cause the exposed portion of the resist layer 126 to be chemically changed or modified such that it may be dissolved and removed when the resist layer 126 is exposed to a developer solution. Alternatively in a negative tone photoresist, the energy adsorption may result in chemical changes in the exposed portion of the resist layer 126 that cause it to be insoluble to a developer. The energy source may include light, such as, for example, visible light, ultra-violet light, or deep ultra-violet light. The energy source may include amplified light, such as, for example a laser. In yet another embodiment, the energy source may include x-rays. Once the portions of the resist layer 126 are removed, one or more trenches 128 may be formed. The portions of the resist layer 126 may be removed selective to the reflective layer 124. The one or more trenches 128 may expose an upper surface of the reflective layer 124.

Referring now to FIG. 1H, a cross section view illustrating removing portions of the reflective layer 124 exposed by the one or more trenches 128 is shown. The portions of the reflective layer 124 may be removed selective to the resist layer 126 and the epitaxial layer 122. The portions of the reflective layer 124 may be removed using a conventional etching process, such as, for example, wet etching, plasma etching, and reactive ion etching (RIE). Removing the portions of the reflective layer 124 from the one or more trenches 128 may expose an upper surface 130 of the epitaxial layer 122.

Referring now to FIG. 11, a cross section view illustrating forming isolation regions 132 within the epitaxial layer 122 is shown. The isolation regions 132 may be formed by introducing dopant atoms below the upper surface 130 of the epitaxial layer 122. In an example, the dopant atoms may be introduced through a conventional ion implantation process. The dopant atoms may be implanted in an ion implantation step through the one or more trenches 128 through the active region 127 of the epitaxial layer 122. The isolation regions 132 may correspond to the non-conductive lanes described above. The isolation regions 132 may electrically isolate portions of the active region of the epitaxial layer 122 from one another. These isolated portions may define pixels 134. The pixels 134 may be similar to the pixels 111 described above. The pixels 134 may have a width of approximately 25 μm to approximately 300 μm

The dopant atoms may be atoms or molecules that provide electrical isolation between portions of the active region 127. For example, the dopant atoms may be protons such as, for example hydrogen, argon, and/or helium. The isolation regions 132 may have a uniform or non-uniform distribution of the dopant atoms. The isolation regions 132 may have a depth Y132 from the upper surface 130. The depth Y132 may extend through the epitaxial layer 122 to at least a distance that extends through the active region 127. In an embodiment, the depth Y132 may be approximately 0.5 μm to several microns. The isolation regions 132 may have a width of approximately 1 μm to approximately 100 μm.

The dopant atoms may be implanted in a direction that is normal to the upper surface 130 of the epitaxial layer 122. While the implant angle (i.e., the angle between the impinging dopant atoms and the surface normal to the upper surface 130), may be nominally zero, non-substantial deviations from normal incidence may be used for the dopant atom implantation step to minimize any adverse effect of channeling of ions.

The dopant atoms may be implanted using a single ion implantation step employing a target ion implantation energy and a target dose, or may be implanted using multiple ion implantation steps each having different target ion implantation energy and a target dose. If multiple ion implantation steps having different ion energies are employed, the dopant profile after the multiple ion implantation steps may be the superposition of all individual ion implantation steps. The target ion implantation energy may range from 20 keV to 1 MeV, although lesser and greater target ion implantation energies may be employed.

FIG. 1J shows another example of the isolation regions 132. In this example, the isolation regions 132 may have one or more underlap regions 136 extending laterally in the epitaxial layer 122 below the reflective layer 124. The underlap portions 136 may be a result of the ion implantation process and may include the dopant atoms implanted during the ion implantation process. The dopant atoms may diffuse laterally in the epitaxial layer 122 such that they have a width X₁₃₆ approximately 0.1 μm to approximately 0.5 μm. It should be noted that the underlap portions 136 may be present in any of the embodiments described herein.

FIG. 1K shows another example of the isolation regions 132. In this example, the isolation regions 132 may have a width that is less than the width of the trench 128. This may be a result of the ion implantation process. It should be noted that isolation regions 132 having a smaller width than the trench 128 may be present in any of the embodiments described herein.

Referring now to FIG. 1L, a cross section view illustrating removing the resist layer 126 is shown. The resist layer 126 may be removed selective to the reflective layer 124 and the isolation regions 132. The resist layer 126 may be removed using a conventional process, such as stripping or a wet etch. The removal of the resist layer 126 may expose the reflective layer 124.

Referring now to FIG. 1M, a cross section view illustrating forming a p-type contact layer 138 on the reflective layer 124 is shown. The p-type contact layer 138 may be formed using a conventional deposition technique, such as, for example, CVD, PECVD, MOCVD, ALD, evaporation, reactive sputtering, chemical solution deposition, spin-on deposition, or other like processes. In an example, the p-type contact layer 138 may be blanket deposited over the reflective layer 124 and the isolation regions 132 and then patterned and etched to expose the upper surface 130. The p-type contact layer 138 may compose one or more layers of a conductive metal or metal alloy, such as, gold, silver, copper.

Referring now to FIG. 1N, a cross section view illustrating removing the sapphire substrate 120 is shown. The sapphire substrate 120 may be removed by a conventional process such as grinding, chemical mechanical polishing (CMP), or laser lift-off. The removal of the sapphire substrate 120 may expose a bottom surface 1002 of the epitaxial layer 122. In an example, the bottom surface 1002 may be roughened after it is exposed.

It should be noted that the isolation regions 132 may be formed using a conventional patterning and etching process in which a portion of the epitaxial layer 122 exposed by the trench 128 may be removed to form an opening. The opening may be filled with a dielectric material such as an oxide or a nitride using a conventional deposition process. Isolation regions 132 composed of dielectric material may be present in any of the embodiments described herein.

Referring now to FIG. 10, a cross section view illustrating forming a common n-contact layer 140 on the bottom surface 1002 of the epitaxial layer 122 is shown. The common n-contact layer 140 may compose a blanket transparent conductor. In an example, the common n-type contact layer 140 may compose a transparent conductive oxide (TCO), such as indium tin oxide (ITO). The common n-type contact layer 140 may be formed using a conventional deposition technique, such as, for example, CVD, PECVD, MOCVD, ALD, evaporation, reactive sputtering, chemical solution deposition, spin-on deposition, or other like processes. Because the sapphire substrate 120 is removed, a wavelength converting layer 142 may be mounted directly on the common n-type contact layer 140 directly below the pixels 134.

The wavelength converting layer 142 may compose elemental phosphor or compounds thereof. The wavelength converting layer 142 may be formed using a conventional deposition technique, such as, for example, CVD, plasma enhanced chemical vapor deposition (PECVD), MOCVD, atomic layer deposition (ALD), evaporation, reactive sputtering, chemical solution deposition, spin-on deposition, or other like processes.

The wavelength converting layer 142 may contain one or more phosphors. Phosphors are luminescent materials that may absorb an excitation energy (usually radiation energy), and then emit the absorbed energy as radiation of a different energy than the initial excitation energy. The phosphors may have quantum efficiencies near 100%, meaning nearly all photons provided as excitation energy may be reemitted by the phosphors. The phosphors may also be highly absorbent. Because the light emitting active region may emit light directly into the highly efficient, highly absorbent wavelength converting layer 142, the phosphors may efficiently extract light from the device. The phosphors used in the wavelength converting layer 142 may include, but are not limited to any conventional green, yellow, and red emitting phosphors.

The wavelength converting layer 142 may be formed by depositing grains of phosphor on the common n-contact layer 140. The phosphor grains may be in direct contact with the common n-contact layer 140, such that light emitted from an active region may be directly coupled to the phosphor grains. Although not shown in FIG. 1V, an optical coupling medium may be provided to hold the phosphor grains in place. The optical coupling medium may be selected to have a refractive index that is as close as possible without significantly exceeding the index of refraction of the epitaxial layer 146. For most efficient operation, no lossy media may be included between the epitaxial layer 146, the phosphor grains of the wavelength converting layer 142, and the optical coupling medium.

The phosphor grains may have a grain size between 0.1 μm and 20 μm. The phosphor grains may be applied by, for example, electrophoretic deposition, spin coating, spray coating, screen printing, or other printing techniques to form the wavelength converting layer 142. In techniques such as spin coating or spray coating, the phosphor may be disposed in a slurry with an organic binder, which may then evaporated after deposit of the slurry by, for example, heating. Optionally, the optical coupling medium may then be applied. Phosphor particles may be nanoparticles themselves (i.e., particles ranging from 100 nm to 1000 nm in size). Spherical phosphor particles, typically produced by spray pyrolysis methods or other methods can be applied, yielding a layer with a high package density which provides advantageous scattering properties. Also, phosphors particles may be coated, for example with a material with a band gap larger than the light emitted by the phosphor, such as SiO₂, Al₂O₃, MePO₄ or -polyphosphate, or other suitable metal oxides.

The wavelength converting layer 142 may be a ceramic phosphor, rather than a phosphor powder. A ceramic phosphor may be formed by heating a powder phosphor at high pressure until the surface of the phosphor particles begin to soften and melt. The partially-melted particles may stick together to form a rigid agglomerate of particles. Uniaxial or isostatic pressing steps and vacuum sintering of the preformed “green body” may be necessary to form a polycrystalline ceramic layer. The translucency of the ceramic phosphor (i.e., the amount of scattering it produces) may be controlled from high opacity to high transparency by adjusting the heating or pressing conditions, the fabrication method, the phosphor particle precursor used, and the suitable crystal lattice of the phosphor material. Besides phosphor, other ceramic forming materials such as alumina may be included, for example to facilitate formation of the ceramic or to adjust the refractive index of the ceramic.

The wavelength converting layer 142 may compose a mixture of silicone and phosphor particles. In this example, the wavelength converting layer 142 may be diced from plates and placed on a lower surface of the common n-contact layer 140.

An alternative process of forming the pixels 111 is described in detail below. In an example, a laterally extending sapphire substrate may be partially or completely removed to reduce adverse effects to pixel optical isolation due to light waveguide properties of the continuous sapphire substrate. Walls attached to the epitaxial layer 146 may retain and define a well for phosphor power deposition. The walls may be additively formed (e.g., by plating metal), subtractively formed (e.g., by etching the sapphire substrate), or may be formed by a combination of the processes.

Referring now to FIG. 1P, a cross section view of a reflective layer 148 formed on an epitaxial layer 146 is shown. The epitaxial layer 146 may be formed on a sapphire substrate 144. The sapphire substrate 144 may be similar to the sapphire substrate 120 described above and may be formed using similar methods as those described above. The epitaxial layer 146 may be similar to the epitaxial layer 122 described above and may be formed using similar methods as those described above.

Referring now to FIG. 1Q, a cross section view illustrating removing portions of the reflective layer 148 and the epitaxial layer 146 is shown. The portions of the reflective layer 148 and the epitaxial layer 146 may be removed using a conventional etching process, such as, for example, wet etching, plasma etching, and RIE. The etching process may form one or more pixels 157 similar to the pixels 134 described above. The reflective layer 148 may be etched such that portions 150 adjacent to the etched portions of the epitaxial layer have one or more angled sidewalls.

Referring now to FIG. 1R, a cross section view of forming a dielectric layer 152 and an n-type contact 154 is shown. The dielectric layer 152 may compose electrically insulating material, such as, for example an oxide or a nitride. The dielectric layer 152 may be formed on the epitaxial layer 146 using a conventional conformal deposition process. Portions of the dielectric layer 152 may be removed using a conventional patterning and etching process to expose portions of the epitaxial layer 146. The n-type contact 154 may compose a blanket transparent conductor. In an example, the n-type contact layer 154 may compose a TCO, such as indium tin oxide ITO. The n-type contact layer 154 may be formed using a conventional deposition technique, such as, for example, CVD, PECVD, MOCVD, ALD, evaporation, reactive sputtering, chemical solution deposition, spin-on deposition, or other like processes. The n-type contact layer 154 may be formed using a conformal deposition process. The n-type contact layer 154 may be in contact with the epitaxial layer 146 in areas exposed by openings in the dielectric layer 152.

Referring now to FIG. 1S, a cross section view of a LED array 1200 is shown. It should be noted that the LED array 1200 may take any configuration and still be consistent with the embodiments described herein. In an example, the LED array 1200 may be a conventional LED array formed on the sapphire substrate 144 using conventional techniques. In another example, the LED array 1200 may be formed using the techniques described above.

A portion of the n-type contact layer 154 and a portion of the dielectric layer 152 may be removed to expose an upper surface of a pixel 157. A p-type contact 156 may be formed on the exposed surface of the pixel 157. The p-type contact 156 may be formed using a conventional deposition technique, such as, for example, CVD, PECVD, MOCVD, ALD, evaporation, reactive sputtering, chemical solution deposition, spin-on deposition, or other like processes. The p-type contact 156 may compose one or more layers of a conductive metal or metal alloy, such as, gold, silver, copper.

Referring now to FIGS. 13-15, cross section views illustrating a method of forming a well for phosphor deposition are shown. FIG. 1T illustrates removing the sapphire substrate 144 from the epitaxial layer 146. The sapphire substrate 144 may be completely removed from the epitaxial layer 146, exposing a lower surface 158 of the epitaxial layer 146. The sapphire substrate 144 may be removed by a conventional process such as grinding, chemical mechanical polishing (CMP), or laser lift-off.

FIG. 1U illustrates forming walls 160 on the lower surface 158 of the epitaxial layer 146. The walls 160 may compose any type of material that can be deposited on the lower surface and provide a desired degree of physical and optical isolation between one or more wavelength converting layers. For example, the walls may compose a dielectric material, a metal, a semiconductor material, or combinations thereof. The walls 160 may be formed using a conventional deposition technique, such as, for example, CVD, PECVD, MOCVD, ALD, evaporation, reactive sputtering, chemical solution deposition, spin-on deposition, or other like processes. In an example, the walls 160 may be formed by depositing a blanket layer on the lower surface 158. The blanket layer may be patterned and etched to form the walls 160. In another example, a resist layer (not shown) may be formed on the lower surface 158. The resist layer may be patterned and etched to form openings. The walls 160 may be formed by depositing the desired materials within the openings and subsequently removing the excess material and resist layer. In another example, the walls 160 may be formed using selective plating. The walls 160 may be located on the lower surface 158 such that they are directly below areas separating the pixels 157. The walls 160 may define wells 162 below the pixels 157.

FIG. 1V illustrates forming a wavelength converting layer 164 within the wells 162. The wavelength converting layer 164 may compose elemental phosphor or compounds thereof. The wavelength converting layer 164 may be formed using a conventional deposition technique, such as, for example, CVD, plasma enhanced chemical vapor deposition (PECVD), MOCVD, atomic layer deposition (ALD), evaporation, reactive sputtering, chemical solution deposition, spin-on deposition, or other like processes.

The wavelength converting layer 164 may contain one or more phosphors. Phosphors are luminescent materials that may absorb an excitation energy (usually radiation energy), and then emit the absorbed energy as radiation of a different energy than the initial excitation energy. The phosphors may have quantum efficiencies near 100%, meaning nearly all photons provided as excitation energy may be reemitted by the phosphors. The phosphors may also be highly absorbent. Because the light emitting active region may emit light directly into the highly efficient, highly absorbent wavelength converting layer 164, the phosphors may efficiently extract light from the device. The phosphors used in the wavelength converting layer 164 may include, but are not limited to any conventional green, yellow, and red emitting phosphors.

The wavelength converting layer 164 may be formed by depositing grains of phosphor on the lower surface 158. The phosphor grains may be in direct contact with the epitaxial layer 146, such that light emitted from an active region may be directly coupled to the phosphor grains. Although not shown in FIG. 1V, an optical coupling medium may be provided to hold the phosphor grains in place. The optical coupling medium may be selected to have a refractive index that is as close as possible without significantly exceeding the index of refraction of the epitaxial layer 146. For most efficient operation, no lossy media may be included between the epitaxial layer 146, the phosphor grains of the wavelength converting layer 164, and the optical coupling medium.

The phosphor grains may have a grain size between 0.1 μm and 20 μm. The phosphor grains may be applied by, for example, electrophoretic deposition, spin coating, spray coating, screen printing, or other printing techniques to form the wavelength converting layer 164. In techniques such as spin coating or spray coating, the phosphor may be disposed in a slurry with an organic binder, which may then evaporated after deposit of the slurry by, for example, heating. Optionally, the optical coupling medium may then be applied. Phosphor particles may be nanoparticles themselves (i.e., particles ranging from 100 nm to 1000 nm in size). Spherical phosphor particles, typically produced by spray pyrolysis methods or other methods can be applied, yielding a layer with a high package density which provides advantageous scattering properties. Also, phosphors particles may be coated, for example with a material with a band gap larger than the light emitted by the phosphor, such as SiO₂, Al₂O₃, MePO₄ or -polyphosphate, or other suitable metal oxides.

The wavelength converting layer 164 may be a ceramic phosphor, rather than a phosphor powder. A ceramic phosphor may be formed by heating a powder phosphor at high pressure until the surface of the phosphor particles begin to soften and melt. The partially-melted particles may stick together to form a rigid agglomerate of particles. Uniaxial or isostatic pressing steps and vacuum sintering of the preformed “green body” may be necessary to form a polycrystalline ceramic layer. The translucency of the ceramic phosphor (i.e., the amount of scattering it produces) may be controlled from high opacity to high transparency by adjusting the heating or pressing conditions, the fabrication method, the phosphor particle precursor used, and the suitable crystal lattice of the phosphor material. Besides phosphor, other ceramic forming materials such as alumina may be included, for example to facilitate formation of the ceramic or to adjust the refractive index of the ceramic.

The wavelength converting layer 164 may compose a mixture of silicone and phosphor particles. In this example, the wavelength converting layer 164 may be diced from plates and placed on the lower surface 158 of the epitaxial layer 146.

Referring now to FIGS. 16-17, cross section views illustrating another method of forming a well for phosphor deposition are shown. FIG. 1W illustrates removing portions of the sapphire substrate 144 from the epitaxial layer 146. The portions of the sapphire substrate 144 may be removed from the epitaxial layer 146, exposing the lower surface 158 of the epitaxial layer 146. The sapphire substrate 144 may be removed by a conventional etching process. The remaining portions of the sapphire substrate 144 may form walls 166 located on the lower surface 158 such that they are directly below areas separating the pixels 157. The walls 166 may define wells 168 below the pixels 157.

FIG. 1X illustrates forming a wavelength converting layer 170 within the wells 168. The wavelength converting layer 170 may compose elemental phosphor or compounds thereof. The wavelength converting layer 164 may be formed using a conventional deposition technique, such as, for example, CVD, plasma enhanced chemical vapor deposition (PECVD), MOCVD, atomic layer deposition (ALD), evaporation, reactive sputtering, chemical solution deposition, spin-on deposition, or other like processes.

The wavelength converting layer 170 may contain one or more phosphors. Phosphors are luminescent materials that may absorb an excitation energy (usually radiation energy), and then emit the absorbed energy as radiation of a different energy than the initial excitation energy. The phosphors may have quantum efficiencies near 100%, meaning nearly all photons provided as excitation energy may be reemitted by the phosphors. The phosphors may also be highly absorbent. Because the light emitting active region may emit light directly into the highly efficient, highly absorbent wavelength converting layer 170, the phosphors may efficiently extract light from the device. The phosphors used in the wavelength converting layer 170 may include, but are not limited to any conventional green, yellow, and red emitting phosphors.

The wavelength converting layer 170 may be formed by depositing grains of phosphor on the lower surface 158. The phosphor grains may be in direct contact with the epitaxial layer 146, such that light emitted from an active region may be directly coupled to the phosphor grains. Although not shown in FIG. 1X, an optical coupling medium may be provided to hold the phosphor grains in place. The optical coupling medium may be selected to have a refractive index that is as close as possible without significantly exceeding the index of refraction of the epitaxial layer 146. For most efficient operation, no lossy media may be included between the epitaxial layer 146, the phosphor grains of the wavelength converting layer 170, and the optical coupling medium.

The phosphor grains may have a grain size between 0.1 μm and 20 μm. The phosphor grains may be applied by, for example, electrophoretic deposition, spin coating, spray coating, screen printing, or other printing techniques to form the wavelength converting layer 170. In techniques such as spin coating or spray coating, the phosphor may be disposed in a slurry with an organic binder, which may then evaporated after deposit of the slurry by, for example, heating. Optionally, the optical coupling medium may then be applied. Phosphor particles may be nanoparticles themselves (i.e., particles ranging from 100 nm to 1000 nm in size). Spherical phosphor particles, typically produced by spray pyrolysis methods or other methods can be applied, yielding a layer with a high package density which provides advantageous scattering properties. Also, phosphors particles may be coated, for example with a material with a band gap larger than the light emitted by the phosphor, such as SiO₂, Al₂O₃, MePO₄ or -polyphosphate, or other suitable metal oxides.

The wavelength converting layer 170 may be a ceramic phosphor, rather than a phosphor powder. A ceramic phosphor may be formed by heating a powder phosphor at high pressure until the surface of the phosphor particles begin to soften and melt. The partially-melted particles may stick together to form a rigid agglomerate of particles. Uniaxial or isostatic pressing steps and vacuum sintering of the preformed “green body” may be necessary to form a polycrystalline ceramic layer. The translucency of the ceramic phosphor (i.e., the amount of scattering it produces) may be controlled from high opacity to high transparency by adjusting the heating or pressing conditions, the fabrication method, the phosphor particle precursor used, and the suitable crystal lattice of the phosphor material. Besides phosphor, other ceramic forming materials such as alumina may be included, for example to facilitate formation of the ceramic or to adjust the refractive index of the ceramic.

The wavelength converting layer 170 may compose a mixture of silicone and phosphor particles. In this example, the wavelength converting layer 170 may be diced from plates and placed on the lower surface 158 of the epitaxial layer 146.

Referring now to FIGS. 18-20, cross section views illustrating another method of forming a well for phosphor deposition are shown. FIG. 1Y illustrates a cross section view of a LED array 1800 formed on a sapphire substrate 172. It should be noted that the LED array 1800 may take any configuration and still be consistent with the embodiments described herein. In an example, the LED array 1800 may be a conventional LED array formed on the sapphire substrate 158 using conventional techniques. In another example, the LED array 1800 may be formed using the techniques described above.

The LED array 1800 may include an epitaxial layer 174 formed on the sapphire substrate 172. The sapphire substrate 172 may compose a crystalline material, such as aluminum oxide, and may be a commercial sapphire wafer. The sapphire substrate 172 may be etched, pattern, or grooved, such that the sapphire substrate 172 has recesses 176. The recesses 176 may be formed using conventional patterning and etching techniques.

The epitaxial layer 174 may compose any Group III-V semiconductors, including binary, ternary, and quaternary alloys of gallium, aluminum, indium, and nitrogen, also referred to as III-nitride materials. In an example, the epitaxial layer 174 may compose GaN. The epitaxial layer 174 may be formed using conventional deposition techniques, such as MOCVD, MBE, or other epitaxial techniques. In an epitaxial deposition process, chemical reactants provided by one or more source gases are controlled and the system parameters are set so that depositing atoms arrive at a deposition surface with sufficient energy to move around on the surface and orient themselves to the crystal arrangement of the atoms of the deposition surface. Accordingly, the epitaxial layer 174 may be grown on the sapphire substrate 172 using conventional epitaxial techniques. The epitaxial layer 174 may extend into the recesses 176 formed in the sapphire substrate.

The LED array 1800 may also include the reflective layer 148, the dielectric layer 152, the n-type contact 154, and the p-type contact 156. The portions 150 of the reflective layer 148 may be etched such that they have one or more angled sidewalls. The LED array 1800 may have defined pixels 157 similar to those described above. As described above, the LED array 1800 may take any configuration known in the art.

FIG. 1Z illustrates removing the sapphire substrate 172. The sapphire substrate 172 may be removed from the epitaxial layer 174, exposing a lower surface 178 of the epitaxial layer 174. The sapphire substrate 172 may be removed by a conventional etching process. The portions of the epitaxial layer 174 grown in the recesses 182 may form walls 180. The walls 180 may be directly below areas separating the pixels 157. The walls 180 may define wells 182 below the pixels 157.

FIG. 1AA illustrates forming a wavelength converting layer 184 within the wells 182. The wavelength converting layer 184 may compose elemental phosphor or compounds thereof. The wavelength converting layer 184 may be formed using a conventional deposition technique, such as, for example, CVD, plasma enhanced chemical vapor deposition (PECVD), MOCVD, atomic layer deposition (ALD), evaporation, reactive sputtering, chemical solution deposition, spin-on deposition, or other like processes.

The wavelength converting layer 184 may contain one or more phosphors. Phosphors are luminescent materials that may absorb an excitation energy (usually radiation energy), and then emit the absorbed energy as radiation of a different energy than the initial excitation energy. The phosphors may have quantum efficiencies near 100%, meaning nearly all photons provided as excitation energy may be reemitted by the phosphors. The phosphors may also be highly absorbent. Because the light emitting active region may emit light directly into the highly efficient, highly absorbent wavelength converting layer 184, the phosphors may efficiently extract light from the device. The phosphors used in the wavelength converting layer 184 may include, but are not limited to any conventional green, yellow, and red emitting phosphors.

The wavelength converting layer 184 may be formed by depositing grains of phosphor on the lower surface 158. The phosphor grains may be in direct contact with the epitaxial layer 174, such that light emitted from an active region may be directly coupled to the phosphor grains. Although not shown in FIG. 1AA, an optical coupling medium may be provided to hold the phosphor grains in place. The optical coupling medium may be selected to have a refractive index that is as close as possible without significantly exceeding the index of refraction of the epitaxial layer 174. For most efficient operation, no lossy media may be included between the epitaxial layer 174, the phosphor grains of the wavelength converting layer 184, and the optical coupling medium.

The phosphor grains may have a grain size between 0.1 μm and 20 μm. The phosphor grains may be applied by, for example, electrophoretic deposition, spin coating, spray coating, screen printing, or other printing techniques to form the wavelength converting layer 184. In techniques such as spin coating or spray coating, the phosphor may be disposed in a slurry with an organic binder, which may then evaporated after deposit of the slurry by, for example, heating. Optionally, the optical coupling medium may then be applied. Phosphor particles may be nanoparticles themselves (i.e., particles ranging from 100 nm to 1000 nm in size). Spherical phosphor particles, typically produced by spray pyrolysis methods or other methods can be applied, yielding a layer with a high package density which provides advantageous scattering properties. Also, phosphors particles may be coated, for example with a material with a band gap larger than the light emitted by the phosphor, such as SiO₂, Al₂O₃, MePO₄ or -polyphosphate, or other suitable metal oxides.

The wavelength converting layer 184 may be a ceramic phosphor, rather than a phosphor powder. A ceramic phosphor may be formed by heating a powder phosphor at high pressure until the surface of the phosphor particles begin to soften and melt. The partially-melted particles may stick together to form a rigid agglomerate of particles. Uniaxial or isostatic pressing steps and vacuum sintering of the preformed “green body” may be necessary to form a polycrystalline ceramic layer. The translucency of the ceramic phosphor (i.e., the amount of scattering it produces) may be controlled from high opacity to high transparency by adjusting the heating or pressing conditions, the fabrication method, the phosphor particle precursor used, and the suitable crystal lattice of the phosphor material. Besides phosphor, other ceramic forming materials such as alumina may be included, for example to facilitate formation of the ceramic or to adjust the refractive index of the ceramic.

The wavelength converting layer 184 may compose a mixture of silicone and phosphor particles. In this example, the wavelength converting layer 184 may be diced from plates and placed on the lower surface 158 of the epitaxial layer 174.

Referring now to FIGS. 1AB-1AD, cross section views illustrating another method of forming a well for phosphor deposition are shown. FIG. 1AB illustrates a cross section view of a LED array 2100 formed on a sapphire substrate 186. It should be noted that the LED array 2100 may take any configuration and still be consistent with the embodiments described herein. In an example, the LED array 2100 may be a conventional LED array formed on the sapphire substrate 186 using conventional techniques. In another example, the LED array 2100 may be formed using the techniques described above.

The LED array 2100 may include an epitaxial layer 188 formed on the sapphire substrate 186. The sapphire substrate 186 may compose a crystalline material, such as aluminum oxide, and may be a commercial sapphire wafer. The sapphire substrate 186 and the epitaxial layer 188 may be etched to form a trench that is subsequently filled with the material used to form the n-type contact 154. The sapphire substrate 186 and the epitaxial layer 188 may be etched using conventional patterning and etching techniques. The n-type contact 154 may extend through at least a portion of the sapphire substrate 186.

The epitaxial layer 188 may compose any Group III-V semiconductors, including binary, ternary, and quaternary alloys of gallium, aluminum, indium, and nitrogen, also referred to as III-nitride materials. In an example, the epitaxial layer 188 may compose GaN. The epitaxial layer 188 may be formed using conventional deposition techniques, such as MOCVD, MBE, or other epitaxial techniques. In an epitaxial deposition process, chemical reactants provided by one or more source gases are controlled and the system parameters are set so that depositing atoms arrive at a deposition surface with sufficient energy to move around on the surface and orient themselves to the crystal arrangement of the atoms of the deposition surface. Accordingly, the epitaxial layer 188 may be grown on the sapphire substrate 172 using conventional epitaxial techniques.

The LED array 2100 may also include the reflective layer 148, the dielectric layer 152, the n-type contact 154, and the p-type contact 156. The portions 150 of the reflective layer 148 may be etched such that they have one or more angled sidewalls. The LED array 1800 may have defined pixels 157 similar to those described above. As described above, the LED array 1800 may take any configuration known in the art.

FIG. 1AC illustrates removing the sapphire substrate 186. The sapphire substrate 186 may be removed from the epitaxial layer 188, exposing a lower surface 190 of the epitaxial layer 188 and the n-type contacts 154. The sapphire substrate 186 may be removed by a conventional etching process. The n-type contacts 154 may form walls 192. The walls 192 may be directly below areas separating the pixels 157. The walls 192 may define wells 194 below the pixels 157.

FIG. 1AD illustrates forming a wavelength converting layer 196 within the wells 194. The wavelength converting layer 196 may compose elemental phosphor or compounds thereof. The wavelength converting layer 196 may be formed using a conventional deposition technique, such as, for example, CVD, plasma enhanced chemical vapor deposition (PECVD), MOCVD, atomic layer deposition (ALD), evaporation, reactive sputtering, chemical solution deposition, spin-on deposition, or other like processes.

The wavelength converting layer 196 may contain one or more phosphors. Phosphors are luminescent materials that may absorb an excitation energy (usually radiation energy), and then emit the absorbed energy as radiation of a different energy than the initial excitation energy. The phosphors may have quantum efficiencies near 100%, meaning nearly all photons provided as excitation energy may be reemitted by the phosphors. The phosphors may also be highly absorbent. Because the light emitting active region may emit light directly into the highly efficient, highly absorbent wavelength converting layer 196, the phosphors may efficiently extract light from the device. The phosphors used in the wavelength converting layer 196 may include, but are not limited to any conventional green, yellow, and red emitting phosphors.

The wavelength converting layer 196 may be formed by depositing grains of phosphor on the lower surface 190. The phosphor grains may be in direct contact with the epitaxial layer 188, such that light emitted from an active region may be directly coupled to the phosphor grains. Although not shown in FIG. 1AD, an optical coupling medium may be provided to hold the phosphor grains in place. The optical coupling medium may be selected to have a refractive index that is as close as possible without significantly exceeding the index of refraction of the epitaxial layer 188. For most efficient operation, no lossy media may be included between the epitaxial layer 188, the phosphor grains of the wavelength converting layer 196, and the optical coupling medium.

The phosphor grains may have a grain size between 0.1 μm and 20 μm. The phosphor grains may be applied by, for example, electrophoretic deposition, spin coating, spray coating, screen printing, or other printing techniques to form the wavelength converting layer 196. In techniques such as spin coating or spray coating, the phosphor may be disposed in a slurry with an organic binder, which may then evaporated after deposit of the slurry by, for example, heating. Optionally, the optical coupling medium may then be applied. Phosphor particles may be nanoparticles themselves (i.e., particles ranging from 100 nm to 1000 nm in size). Spherical phosphor particles, typically produced by spray pyrolysis methods or other methods can be applied, yielding a layer with a high package density which provides advantageous scattering properties. Also, phosphors particles may be coated, for example with a material with a band gap larger than the light emitted by the phosphor, such as SiO₂, Al₂O₃, MePO₄ or -polyphosphate, or other suitable metal oxides.

The wavelength converting layer 196 may be a ceramic phosphor, rather than a phosphor powder. A ceramic phosphor may be formed by heating a powder phosphor at high pressure until the surface of the phosphor particles begin to soften and melt. The partially-melted particles may stick together to form a rigid agglomerate of particles. Uniaxial or isostatic pressing steps and vacuum sintering of the preformed “green body” may be necessary to form a polycrystalline ceramic layer. The translucency of the ceramic phosphor (i.e., the amount of scattering it produces) may be controlled from high opacity to high transparency by adjusting the heating or pressing conditions, the fabrication method, the phosphor particle precursor used, and the suitable crystal lattice of the phosphor material. Besides phosphor, other ceramic forming materials such as alumina may be included, for example to facilitate formation of the ceramic or to adjust the refractive index of the ceramic.

The wavelength converting layer 196 may compose a mixture of silicone and phosphor particles. In this example, the wavelength converting layer 196 may be diced from plates and placed on the lower surface 158 of the epitaxial layer 188.

Referring now to FIG. 1AE, a flowchart illustrating a method of forming a device is shown. In step 131, a trench may be formed in a trench in a p-type contact layer and a reflective layer to expose an epitaxial layer. In step 133, an isolation region may be formed in in the epitaxial layer exposed by the trench using ion implantation. The isolation region may separate a first pixel and a second pixel and may have a width that is at least a width of the trench. In step 135, a common n-type contact layer may be formed on the epitaxial layer. The common n-type contact layer may be distal to the reflective layer. In an optional step 137, a wavelength converting region may be formed on the common n-type contact layer.

It should be noted that the term “distal” as used herein may be used as a directional term to mean a spatially opposites sides of an element, device, layer, or other structure. A first element and a second element that are on distal sides of a third element may be separated from one another by at least a portion of the third element. For example, an upper surface of a layer may be distal to a lower surface of the layer.

FIG. 2A is a top view of an electronics board with an LED array 410 attached to a substrate at the LED device attach region 318 in one embodiment. The electronics board together with the LED array 410 represents an LED system 400A. Additionally, the power module 312 receives a voltage input at Vin 497 and control signals from the connectivity and control module 316 over traces 418B, and provides drive signals to the LED array 410 over traces 418A. The LED array 410 is turned on and off via the drive signals from the power module 312. In the embodiment shown in FIG. 2A, the connectivity and control module 316 receives sensor signals from the sensor module 314 over trace 4180.

FIG. 2B illustrates one embodiment of a two channel integrated LED lighting system with electronic components mounted on two surfaces of a circuit board 499. As shown in FIG. 2B, an LED lighting system 400B includes a first surface 445A having inputs to receive dimmer signals and AC power signals and an AC/DC converter circuit 412 mounted on it. The LED system 400B includes a second surface 445B with the dimmer interface circuit 415, DC-DC converter circuits 440A and 440B, a connectivity and control module 416 (a wireless module in this example) having a microcontroller 472, and an LED array 410 mounted on it. The LED array 410 is driven by two independent channels 411A and 411B. In alternative embodiments, a single channel may be used to provide the drive signals to an LED array, or any number of multiple channels may be used to provide the drive signals to an LED array.

The LED array 410 may include two groups of LED devices. In an example embodiment, the LED devices of group A are electrically coupled to a first channel 411A and the LED devices of group B are electrically coupled to a second channel 411B. Each of the two DC-DC converters 440A and 440B may provide a respective drive current via single channels 411A and 411B, respectively, for driving a respective group of LEDs A and B in the LED array 410. The LEDs in one of the groups of LEDs may be configured to emit light having a different color point than the LEDs in the second group of LEDs. Control of the composite color point of light emitted by the LED array 410 may be tuned within a range by controlling the current and/or duty cycle applied by the individual DC/DC converter circuits 440A and 440B via a single channel 411A and 411B, respectively. Although the embodiment shown in FIG. 2B does not include a sensor module (as described in FIG. 2A), an alternative embodiment may include a sensor module.

The illustrated LED lighting system 400B is an integrated system in which the LED array 410 and the circuitry for operating the LED array 410 are provided on a single electronics board. Connections between modules on the same surface of the circuit board 499 may be electrically coupled for exchanging, for example, voltages, currents, and control signals between modules, by surface or sub-surface interconnections, such as traces 431, 432, 433, 434 and 435 or metallizations (not shown). Connections between modules on opposite surfaces of the circuit board 499 may be electrically coupled by through board interconnections, such as vias and metallizations (not shown).

According to embodiments, LED systems may be provided where an LED array is on a separate electronics board from the driver and control circuitry. According to other embodiments, a LED system may have the LED array together with some of the electronics on an electronics board separate from the driver circuit. For example, an LED system may include a power conversion module and an LED module located on a separate electronics board than the LED arrays.

According to embodiments, an LED system may include a multi-channel LED driver circuit. For example, an LED module may include embedded LED calibration and setting data and, for example, three groups of LEDs. One of ordinary skill in the art will recognize that any number of groups of LEDs may be used consistent with one or more applications. Individual LEDs within each group may be arranged in series or in parallel and the light having different color points may be provided. For example, warm white light may be provided by a first group of LEDs, a cool white light may be provided by a second group of LEDs, and a neutral white light may be provided by a third group.

FIG. 2C shows an example vehicle headlamp system 300 including a vehicle power 302 including a data bus 304. A sensor module 307 may be connected to the data bus 304 to provide data related to environment conditions (e.g. ambient light conditions, temperature, time, rain, fog, etc), vehicle condition (parked, in-motion, speed, direction), presence/position of other vehicles, pedestrians, objects, or the like. The sensor module 307 may be similar to or the same as the sensor module 314 of FIG. 2A. AC/DC Converter 305 may be connected to the vehicle power 302.

The AC/DC converter 312 of FIG. 2C may be the same as or similar to the AC/DC converter 412 of FIG. 2B and may receive AC power from the vehicle power 302. It may convert the AC power to DC power as described in FIG. 2B for AC-DC converter 412. The vehicle head lamp system 300 may include an active head lamp 330 which receives one or more inputs provided by or based on the AC/DC converter 305, connectivity and control module 306, and/or sensor module 307. As an example, the sensor module 307 may detect the presence of a pedestrian such that the pedestrian is not well lit, which may reduce the likelihood that a driver sees the pedestrian. Based on such sensor input, the connectivity and control module 306 may output data to the active head lamp 330 using power provided from the AC/DC converter 305 such that the output data activates a subset of LEDs in an LED array contained within active head lamp 330. The subset of LEDs in the LED array, when activated, may emit light in the direction where the sensor module 307 sensed the presence of the pedestrian. These subset of LEDs may be deactivated or their light beam direction may otherwise be modified after the sensor module 207 provides updated data confirming that the pedestrian is no longer in a path of the vehicle that includes vehicle head lamp system.

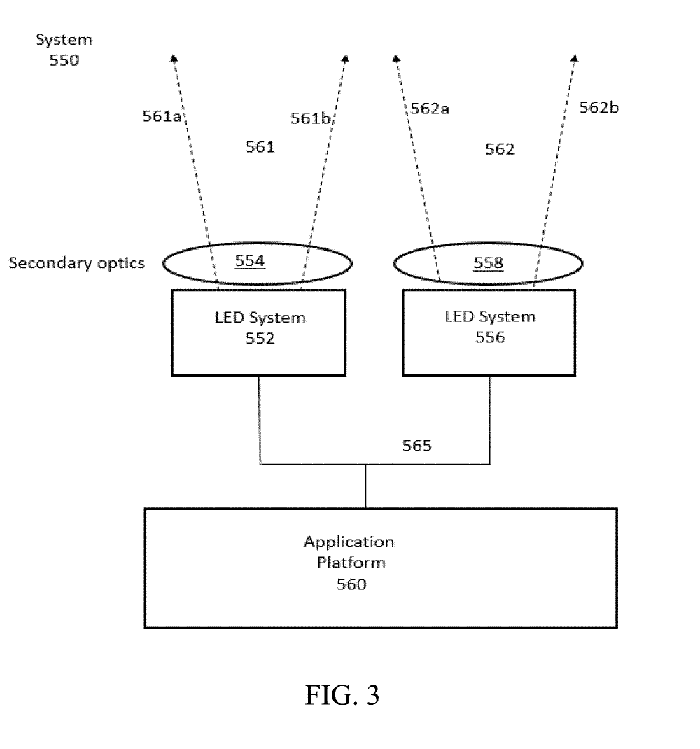

FIG. 3 shows an example system 550 which includes an application platform 560, LED systems 552 and 556, and optics 554 and 558. The LED System 552 produces light beams 561 shown between arrows 561a and 561b. The LED System 556 may produce light beams 562 between arrows 562a and 562b. In the embodiment shown in FIG. 3, the light emitted from LED System 552 passes through secondary optics 554, and the light emitted from the LED System 556 passes through secondary optics 554. In alternative embodiments, the light beams 561 and 562 do not pass through any secondary optics. The secondary optics may be or may include one or more light guides. The one or more light guides may be edge lit or may have an interior opening that defines an interior edge of the light guide. LED systems 552 and/or 556 may be inserted in the interior openings of the one or more light guides such that they inject light into the interior edge (interior opening light guide) or exterior edge (edge lit light guide) of the one or more light guides. LEDs in LED systems 552 and/or 556 may be arranged around the circumference of a base that is part of the light guide. According to an implementation, the base may be thermally conductive. According to an implementation, the base may be coupled to a heat-dissipating element that is disposed over the light guide. The heat-dissipating element may be arranged to receive heat generated by the LEDs via the thermally conductive base and dissipate the received heat. The one or more light guides may allow light emitted by LED systems 552 and 556 to be shaped in a desired manner such as, for example, with a gradient, a chamfered distribution, a narrow distribution, a wide distribution, an angular distribution, or the like.

In example embodiments, the system 550 may be a mobile phone of a camera flash system, indoor residential or commercial lighting, outdoor light such as street lighting, an automobile, a medical device, AR/VR devices, and robotic devices. The LED System 400A shown in FIG. 2A and vehicle head lamp system 300 shown in FIG. 2C illustrate LED systems 552 and 556 in example embodiments.

The application platform 560 may provide power to the LED systems 552 and/or 556 via a power bus via line 565 or other applicable input, as discussed herein. Further, application platform 560 may provide input signals via line 565 for the operation of the LED system 552 and LED system 556, which input may be based on a user input/preference, a sensed reading, a pre-programmed or autonomously determined output, or the like. One or more sensors may be internal or external to the housing of the application platform 560. Alternatively or in addition, as shown in the LED system 400 of FIG. 2A, each LED System 552 and 556 may include its own sensor module, connectivity and control module, power module, and/or LED devices.

In embodiments, application platform 560 sensors and/or LED system 552 and/or 556 sensors may collect data such as visual data (e.g., LIDAR data, IR data, data collected via a camera, etc.), audio data, distance based data, movement data, environmental data, or the like or a combination thereof. The data may be related a physical item or entity such as an object, an individual, a vehicle, etc. For example, sensing equipment may collect object proximity data for an ADAS/AV based application, which may prioritize the detection and subsequent action based on the detection of a physical item or entity. The data may be collected based on emitting an optical signal by, for example, LED system 552 and/or 556, such as an IR signal and collecting data based on the emitted optical signal. The data may be collected by a different component than the component that emits the optical signal for the data collection. Continuing the example, sensing equipment may be located on an automobile and may emit a beam using a vertical-cavity surface-emitting laser (VCSEL). The one or more sensors may sense a response to the emitted beam or any other applicable input.

In example embodiment, application platform 560 may represent an automobile and LED system 552 and LED system 556 may represent automobile headlights. In various embodiments, the system 550 may represent an automobile with steerable light beams where LEDs may be selectively activated to provide steerable light. For example, an array of LEDs may be used to define or project a shape or pattern or illuminate only selected sections of a roadway. In an example embodiment, Infrared cameras or detector pixels within LED systems 552 and/or 556 may be sensors (e.g., similar to sensors module 314 of FIG. 2A and 307 of FIG. 2C) that identify portions of a scene (roadway, pedestrian crossing, etc.) that require illumination.

Having described the embodiments in detail, those skilled in the art will appreciate that, given the present description, modifications may be made to the embodiments described herein without departing from the spirit of the inventive concept. Therefore, it is not intended that the scope of the invention be limited to the specific embodiments illustrated and described.

1. A device comprising:
a trench in a p-type contact layer and a reflective layer, the trench exposing a first surface of an epitaxial layer;
an isolation region in the epitaxial layer aligned with the trench; and
a common n-type contact layer on a second surface of the epitaxial layer distal to the first surface.

2. The device of claim 1, wherein the epitaxial layer comprises a first pixel and a second pixel separated by the isolation region.

3. The device of claim 2, wherein the first pixel and the second pixel have a width of approximately 25 μm to approximately 300 μm.

4. The device of claim 2, wherein the isolation region electrically and optically isolates the first pixel from the second pixel.

5. The device of claim 1, wherein the isolation region extends through an active region in the epitaxial layer.

6. The device of claim 1, further comprising:
a wavelength converting layer on the common n-type contact layer.

7. The device of claim 1, wherein the isolation region comprises one or more protons of helium, argon, and hydrogen.

8. The device of claim 1, wherein the isolation region has a width of approximately 1 μm to approximately 100 μm.

9. A light emitting diode (LED) array comprising:
a trench in a p-type contact layer and a reflective layer, the trench exposing a first surface of an epitaxial layer;
a first pixel and a second pixel in the epitaxial layer separated by an isolation region aligned with the trench; and
a common n-type contact layer on a second surface of the epitaxial layer distal to the first surface.

10. The LED array of claim 9, wherein the isolation region extends through an active region in the epitaxial layer.

11. The LED array of claim 9, further comprising:
a wavelength converting layer on the common n-type contact layer.

12. The LED array of claim 9, wherein the isolation region comprises one or more protons of helium, argon, and hydrogen.

13. The LED array of claim 9, wherein the first pixel and the second pixel have a width of approximately 25 μm to approximately 300 μm.

14. The LED array of claim 9, wherein the isolation region has a width of approximately 1 μm to approximately 100 μm.

15. The LED array of claim 9, wherein the isolation region electrically and optically isolates the first pixel from the second pixel.

16. A method of forming a device, the method comprising:
forming a trench in a p-type contact layer and a reflective layer to expose a first surface epitaxial layer;
forming an isolation region in the epitaxial layer exposed by the trench using ion implantation, the isolation region separating a first pixel and a second pixel; and
forming a common n-type contact layer on a second surface of the epitaxial layer distal to the first surface.

17. The method of claim 16, wherein the isolation region extends through an active region in the epitaxial layer.

18. The method of claim 16, further comprising:
forming a wavelength converting region on the common n-type contact layer.

19. The method of claim 16, wherein the forming the isolation region comprises performing an ion implantation.

20. The method of claim 19, wherein the isolation region comprises one or more protons of helium, argon, and hydrogen.
